(19) United States
(12) Patent Application Publication
(10) Pub. No.: US 2026/0371509 A1
(43) Pub. Date: Nov. 19, 2026

(54) LAMINATE AND DISPLAY DEVICE

(71) Applicant: Konica Minolta, Inc., Tokyo (JP)

(72) Inventors: Hiroto Konaga, Hachioji-shi, Tokyo (JP); Nanae Fujieda, Hino-shi (JP)

(73) Assignee: Konica Minolta, Inc., Tokyo (JP)

(21) Appl. No.: 19/125,569

(22) PCT Filed: Oct. 26, 2023
(86) PCT No.: PCT/JP2023/038692

§ 371 Date: Apr. 29, 2025

(30) Foreign Application Priority Data
Oct. 31, 2022 (JP) 2022-174204

(51) Int. Cl. H05K 5/03; B32B 17/10; B32B 27/20; B32B 27/30

(52) U.S. Cl. CPC H05K 5/03; B32B 17/10; B32B 27/20; B32B 27/308; B32B 2250/03; B32B 2264/0207; B32B 2307/51; B32B 2307/54; B32B 2307/7376; B32B 2457/20

(57) ABSTRACT

A laminate includes a glass layer, an elastic layer, and an optical film. A storage elastic modulus of the elastic layer at 25 °C is within a range of 0.5 to 10.0 MPa. The optical film contains rubber particles. When loss tangents at 25 °C of the elastic layer and the optical film are defined as tan δ1 and tan δ2, respectively, a value of a ratio of the loss tangents (tan δ1/tan δ2) satisfies Formula (1): 1.0≤tan δ1/tan δ2≤3.0.

### TECHNICAL FIELD

The present invention relates to a laminate and a display device. More specifically, the present invention relates to a laminate or the like in which a glass layer has both impact resistance and flexibility.

### BACKGROUND ART

Recently, flexible displays that can be folded and rolled have been actively developed. The flexible display includes a display unit and a cover unit for protecting the display unit.

In a flexible display, flexibility is required for a base material used for a cover unit. Therefore, consideration has been given to changing from a conventionally used glass base material to a resin base material, or to making the glass base material itself a thin film. Among them, ultra-thin glass (UTG) has been mainly used as the base material from the viewpoint of a feeling of quality and anti-crease (durability).

However, the thin film glass has a technological problem that it is weak against impact and is easily broken. In addition, in recent years, development of a display that supports pen input has been advanced, and a cover glass unit capable of withstanding impact at the time of pen input is required. From such a viewpoint, the cover glass unit is required to have higher impact resistance than ever before.

Patent Document 1 discloses a technique relating to a display film including a glass layer and an energy dissipation layer. The technology teaches that an intermediate adhesive layer may be provided between the glass layer and the energy dissipation layer for the purpose of fixing the energy dissipation layer to the glass layer.

However, it has been found that the display film cannot withstand a high impact, and the display film needs to be relatively thick in order to withstand a high impact. Further, when the display film is thickened, the impact resistance is improved but the flexibility is lowered, and therefore, it is difficult to obtain a display film having both impact resistance and flexibility.

Patent Document 2 discloses a technique relating to an adhesive layer for an organic EL display device which has excellent resistance to drop impact. A cover glass unit to which the above-described technique is applied becomes relatively thick even though with excellent resistance to drop impact. Therefore, it has been found that it is difficult to obtain a cover glass unit having both impact resistance and flexibility.

### CITATION LIST

### Patent Literature

Patent Document 1: Japanese Patent No. 7056878
Patent Document 2: Japanese Unexamined Patent Publication No. 2020-139108

### SUMMARY

One or more embodiments of the present invention provide a laminate and a display device in which both impact resistance and bendability of a glass layer are achieved.

The present inventors have completed the present invention by finding that, in a laminate including a glass layer, an elastic layer, and an optical film, when the elastic layer has a storage modulus at 25 °C within a specific range, the optical film contains rubber particles, and the elastic layer and the optical film have a ratio of loss tangents at 25 °C within a specific range, it is possible to provide a laminate having both impact resistance and flexibility in the glass layer.
[1] A laminate according to an aspect of the present invention comprises a glass layer, an elastic layer and an optical film,
wherein a storage elastic modulus of the elastic layer at 25 °C is within a range of 0.5 to 10.0 MPa,
wherein the optical film contains rubber particles, and
wherein, when loss tangents at 25 °C of the elastic layer and the optical film are defined as tan δ₁ and tan 82, respectively, a value of a ratio of the loss tangents (tan δ₁/tan 82) satisfies Formula (1) below,

1.0≤tan δ₁/tan δ₂≤3.0. Formula (1):
[2] In the laminate according to an aspect of the present invention, the storage elastic modulus of the elastic layer at 25 °C is within a range of 1.2 to 8.0 MPa.
[3] In the laminate according to an aspect of the present invention, the value of the ratio of the loss tangents (tan 81/tan 82) satisfies Formula (2) below,

1.8≤tan δ₁/tan δ₂≤3.0. Formula (2):
[4] In the laminate according to an aspect of the present invention, a content of the rubber particles is within a range of 10 to 80% by mass relative to a total mass of the optical film.
[5] In the laminate according to an aspect of the present invention, the optical film contains a thermoplastic (meth)acrylic resin.
[6] In the laminate according to an aspect of the present invention, a thickness of the glass layer is within a range of 10 to 30 μm.
[7] In the laminate according to an aspect of the present invention, a thickness of the elastic layer is within a range of 2 to 15 μm.
[8] A display device according to an aspect of the present invention comprises the laminate described above.
[9] In the display device according to an aspect of the present invention, the glass layer is disposed at a position more outward of the display device than the optical film.

### Advantageous Effects of Invention

According to the above-described means of the present invention, it is possible to provide a laminate and a display device in which a glass layer has both impact resistance and flexibility.

Although the realization mechanism or action mechanism of the effects of the present invention is not clear, the inventors infer the mechanism as follows.

In the related art, a laminate used for a cover glass unit has a configuration in which a thick layer having a relatively low storage elastic modulus is provided under a thin film glass. When pen input is used on such a laminate, that is, on the thin film glass side, the thin film glass may be broken. It is considered that this occurs because, at the time of pen input, outward tensile stress acting on the back surface (the back surface when the surface in contact with a pen is defined as the front surface) of the thin film glass is not suppressed and the thin film glass is bent.

In addition, in the conventional technique, a configuration has been adopted in which a film using polyethylene terephthalate (PET) or polymethyl methacrylate (PMMA) is further provided under the thin film glass. In the case where such a laminate is used as a cover glass unit, an internal module (display unit) may be damaged when an external impact is applied to the display (e.g., dropping). It is considered that this is caused because the loss tangent (tan δ) is small in the film using PET or PMMA, an impact cannot be sufficiently absorbed and transmitted to the internal module.

In the present invention, it is considered that by providing a layer having a relatively high storage elastic modulus under the thin film glass, an outward tensile stress acting on the back surface of the thin film glass can be suppressed at the time of pen input, and the thin film glass can be prevented from being bent. Then, an optical film thereunder is considered to enable further suppression of the outward tensile stress acting on the back surface of the thin film glass.

Furthermore, by making the layer having a relatively high storage elastic modulus thinner, the distance between the thin film glass and the optical film becomes shorter. As a result, it is considered that the effect of suppressing the tensile stress increases, and thus the thin film glass can be more prevented from being bent.

In addition, it is considered that, by making the loss tangent (tan δ) of the optical film relatively large, it is possible to make it difficult for an impact to be transmitted to the internal module, thereby preventing the internal module from being damaged.

These features provide sufficient impact resistance no matter whether the area receiving an impact force is relatively small or large.

In addition, in the present invention, since the optical film contains rubber particles, the loss tangent (tan δ) can be made relatively large and the thickness of the film can be made thin. As this allows the thickness of the laminate to be relatively small, sufficient flexibility is obtained.

### BRIEF DESCRIPTION OF DRAWINGS

FIG. 1 Cross-sectional view of a basic layer configuration of a laminate of the present invention

FIG. 2 Schematic view showing an example of a method of producing thin film glass

### DESCRIPTION OF EMBODIMENTS

A laminate of the present invention is a laminate including a glass layer, an elastic layer, and an optical film, wherein a storage elastic modulus of the elastic layer at 25 °C is in a range of 0.5 to 10.0 MPa, the optical film contains rubber particles, and when loss tangents of the elastic layer and the optical film at 25 °C are defined as tan δ₁ and tan δ₂, respectively, a value of a ratio of the loss tangents (tan δ₁/tan δ₂) satisfies the following formula (1).

1.0≤tan δ₁/tan δ₂≤3.0 Formula (1):

This feature is a technical feature common to or corresponding to the following embodiments.

In an embodiment of the present invention, from the viewpoint of achieving both impact resistance and bendability of the glass layer, the storage modulus of the elastic layer at 25 °C is preferably in a range of 1.2 to 8.0 MPa.

In an embodiment of the present invention, from the viewpoint of achieving both impact resistance and bendability in the glass layer, the value of the ratio of loss tangents (tan δ₁/tan δ₂) preferably satisfies Formula (2) above.

In an embodiment of the present invention, the content of the rubber particles is preferably in the range of 10 to 80 mass % relative to the total mass of the optical film, from the viewpoint that the optical film has appropriate hardness and the optical film can obtain a desired loss tangent (tan δ₂/).

In an embodiment of the present invention, from the viewpoint of storage property and transparency, the optical film preferably contains a thermoplastic (meth)acrylic resin.

In an embodiment of the present invention, it is preferable that the glass layer has a thickness in a range of 10 to 30 μm from the viewpoint of bendability of the glass layer.

In an embodiment of the present invention, from the viewpoint of achieving both impact resistance and flexibility in the glass layer, the thickness of the elastic layer is preferably in a range of 2 to 15 μm.

A display device according to the present invention includes the laminate according to the present invention.

In addition, from the viewpoint of exhibiting the effect of the present invention, the display device of the present invention is a display device including the laminate of the present invention, and the glass layer is preferably disposed at a position more outward of the display device than the optical film.

Hereinafter, the present invention, constituent elements thereof, and forms and aspects for carrying out the present invention will be described in detail. In the present description, when two figures are used to indicate a range of value before and after “to”, these figures are included in the range as a lower limit value and an upper limit value.

### 1. Summary of Laminate

A laminate of the present invention is a laminate including a glass layer, an elastic layer, and an optical film, wherein a storage elastic modulus of the elastic layer at 25 °C is in a range of 0.5 to 10.0 MPa, the optical film contains rubber particles, and when loss tangents of the elastic layer and the optical film at 25 °C are defined as tan δ₁ and tan δ₂, respectively, a value of a ratio of the loss tangents (tan δ₁/tan δ₂) satisfies the following Formula (1).

1.0≤tan δ₁/tan δ₂≤3.0 Formula (1):

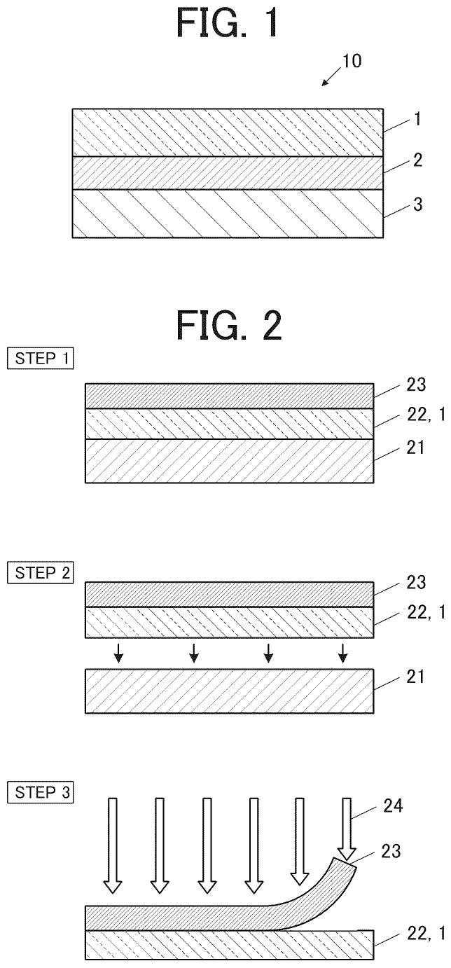

FIG. 1 is a cross-sectional view of a basic layer configuration of a laminate of the present invention. The laminate 10 includes a glass layer 1, an elastic layer 2, and an optical film 3. If necessary, another layer may be disposed between the layers. Furthermore, the order of arrangement of the respective layers is not particularly limited, but it is preferable to arrange the elastic layer 2 between the glass layer 1 and the optical film 3 from the viewpoint of exhibition of the effect. The boundary between the elastic layer and the optical film is not necessarily clear, and a layer structure in which the elastic layer and the optical film are integrated may be employed.

In the case where the elastic layer and the optical film are integrated in a layer structure, the loss tangents at 25 °C of the upper 30% and the lower 30% in the film thickness direction are defined as tan δ3 and tan δ4, respectively. Here, when the value of the ratio of the loss tangents (tan δ3/tan δ4) satisfies the following Formula (3), the present invention applies.

1.0≤tan δ₃/tan δ₄≤3.0 Formula (3):

An object having both properties as an elastic body and properties as a viscous body is referred to as a “viscoelastic body”. The properties as a viscoelastic body can be expressed by a dynamic elastic modulus.

That is, the “dynamic elastic modulus” is a physical quantity representing properties of an object as a viscoelastic body, and the dynamic elastic modulus is defined as a ratio between oscillating stress and strain generated thereby.

The dynamic elastic modulus is generally expressed by a complex number (also referred to as a “complex elastic modulus”), and can be decomposed into two terms of a “storage elastic modulus” corresponding to a real part and a “loss elastic modulus” corresponding to an imaginary part.

The storage elastic modulus corresponds to a portion stored as elastic energy when a material is deformed, and is an index indicating the degree of hardness. That is, it can be determined that the higher the value of the storage elastic modulus is, the harder the object is, and the lower the value of the storage elastic modulus is, the softer the object is.

The loss elastic modulus corresponds to a loss energy portion dissipated by internal friction or the like when a material is deformed, and is an index representing the degree of viscosity.

Further, the ratio of the storage elastic modulus to the loss elastic modulus is referred to as “loss tangent” and is represented by the following formula.

loss tangent (tan δ)=loss elastic modulus/storage elastic modulus Formula:

As the value of the loss tangent is larger, the tendency of viscosity is stronger, the deformation behavior becomes liquid-like, and the repulsive elastic energy tends to be smaller. That is, it can be determined that the larger the value of the loss tangent is, the higher the stress relaxation property of the object is, and the lower the value of the storage elastic modulus is, the higher the rigidity of the object is.

### 2. Configuration of Laminate

The laminate of the present invention includes a glass layer, an elastic layer, and an optical film.

Hereinafter, each layer will be described.

### (1) Glass Layer

### (1.1) Configuration of Glass Layer (Thin Film Glass)

The glass layer according to the present invention is preferably thin film glass. Examples of the material of the thin film glass include lithium aluminosilicate glass, soda lime glass, borosilicate glass, alkali metal aluminosilicate glass, and aluminosilicate glass having a low alkali content.

The thin film glass is preferably alkali-free glass which does not substantially contain alkali components. Specifically, the content of the alkali components is preferably 1000 ppm by mass or less, more preferably 500 ppm by mass or less, and still more preferably 300 ppm by mass or less, relative to the total mass of the thin film glass.

By reducing the alkali components, substitution of cations on the surface of the thin film glass can be suppressed, and a phenomenon called soda blowing can be suppressed. This makes it possible to suppress a decrease in the density of the surface of the thin film glass and to make the thin film glass less likely to be broken.

### (1.2) Method of Producing Glass Layer (Thin Film Glass)

The thin film glass (glass layer) can be produced by a generally known method, for example, a float method, a downdraw method, an overflow downdraw method or the like. Among these, the overflow downdraw method or the float method is preferable because the surface of the thin film glass does not come in contact with a forming member at the time of production and the surface of the thin film glass to be obtained is hardly scratched. Among these, the float method is preferable from the viewpoint that the thickness of the thin film glass can be made less than 200 μm.

Usually, as the thickness of glass is smaller, the strength of glass is lower and glass is more likely to be broken, and therefore, it is difficult to handle and process thin film glass alone. However, handling and processing of the thin film glass can be facilitated by processing the thin film glass while temporarily bonding it to a thicker support substrate (hereinafter, also referred to as a “carrier substrate”) and peeling off the support substrate as a post-processing step.

For example, according to the technology described in International Publication No. 2017/066924, soda-lime glass having a thickness of less than 100 μm can be produced by the following steps. FIG. 2 is a schematic view showing an example of a method of producing thin film glass.

### (Step 1)

As shown in FIG. 2, in Step 1, thin film glass 22 is formed on a carrier substrate 21 having a bonding surface so that a first surface of the thin film glass is in contact with the carrier substrate 21. Then, a contact film 23 having an adhesive force (hereinafter, also referred to as a “contact film”) is pressure-bonded to a second surface opposite to the first surface.

That is, a material of the thin film glass is poured onto the carrier substrate 21 having a sufficient strength and a thickness for easy processing so as to have a desired thickness. Thus, the first surface of the thin film glass 22 is formed so as to be in contact with the carrier substrate 21. Thereafter, the contact film 23 is pressure-bonded to the second surface opposite to the first surface.

### (Step 2)

As illustrated in FIG. 2, in Step 2, the thin film glass 22 is peeled off from the carrier substrate 21 by the contact film 23 having a high adhesive force.

### (Step 3)

As shown in FIG. 2, in Step 3, weakening processing (electromagnetic irradiation 24) for weakening the adhesive force of the contact film is performed. Thus, the contact film 23 is removed from the second surface of the thin film glass 22.

In this way, by using the contact film 23 for securely holding the thin film glass 22, the thin film glass 22 can be protected. The exposed surface of the thin film glass 22 can be protected, for example, from mechanical damage and can be handled safely and simply.

Examples of the material of the contact film include polyolefins (PO) such as polyethylene terephthalate (PET) and polyethylene (PE).

The contact film is usually bonded to the thin film glass by an adhesive layer made of an adhesive provided on one surface of the substrate. The contact film may be directly bonded to the thin film glass by the adhesiveness of the contact film itself.

The adhesive force between the contact film and the second surface of the thin film glass is appropriately selected so that a force sufficient for peeling off the thin film glass from the carrier substrate is transmitted by a peeling device.

The shape of the contact film is preferably a foil or a tape. By forming a foil or tape, it can be wound into a roll. The thickness of the contact film is preferably 50 μm or more, preferably 80 μm or more, more preferably 125 μm or more, and particularly preferably 150 μm or more.

The thin film glass is preferably produced on the carrier substrate by the above-described downdraw method, overflow downdraw method, float method, or the like.

The thickness of the carrier substrate is preferably 100 μm or more, more preferably 300 μm or more, and still more preferably 500 μm or more.

Furthermore, the width direction dimension of the carrier substrate is preferably 3 inches (1 inch is 2.54 cm) or more, more preferably 6 inches or more, still more preferably 8 inches or more, and particularly preferably 12 inches or more.

In particular, the carrier substrate preferably has a glass substrate size of the first generation or larger, and for example, preferably has a size of the second generation to the eighth generation. Alternatively, for example, a larger size of 1×1 m to 3×3 m may be adopted. The carrier substrate may be of various shapes, such as rectangular, oval, circular, etc.

The thin film glass is peeled off from the carrier substrate together with the contact film by the adhesive force of the contact film. Thereafter, the contact film is peeled off, and single thin film glass is obtained.

It is preferable to reduce the adhesive force by treating the contact film with weakening processing of the adhesive force before the contact film is peeled off from the thin film glass. To be specific, it is preferable to reduce the adhesive strength to 0.5 N/25 mm or less.

In the weakening processing, for example, electromagnetic radiation such as infrared rays, ultraviolet rays, and visible light is preferably used as appropriate. The electromagnetic radiation may be narrowband or may cover a wider band, corresponding to the adhesive material used. It may also be laser radiation.

Above all, it is preferred to select electromagnetic radiation having a wavelength outside the visible spectrum so that the adhesion does not deteriorate under exposure to visible light. Some commercially available adhesive materials, which can be at least partially deactivated by irradiation with electromagnetic radiation, can be used as a contact film.

When the adhesiveness of the contact film is reduced by increasing or decreasing the temperature, heat processing may be used as the weakening processing.

The electromagnetic irradiation is preferably performed from the outer surface of the contact film, that is, from the surface on the side to which the thin film glass is not bonded.

Examples of the contact film include “NDS4150-20” (manufactured by Daoming Optics and Chemical Co., Ltd) and the like. An example of the weakening processing corresponding thereto is irradiation with ultraviolet light having the wavelength 365 nm.

Specific methods and conditions for producing the thin film glass will be described in the section of Examples. In addition, as the thin film glass, for example, commercially available products manufactured by SCHOTT Corporation, Nippon Electric Glass Co., Ltd, and the like can be used.

The thickness of the thin film glass is preferably within a range of 10 to 50 μm. When the thickness of the thin film glass is 10 μm or more, sufficient impact resistance of the laminate can be obtained. On the other hand, when the thickness of the thin film glass is 50 μm or less, sufficient flexibility of the laminate can be obtained.

From the viewpoint of achieving both impact resistance and flexibility, the thickness of the thin film glass is more preferably in a range of 10 to 40 μm, and still more preferably in a range of 10 to 30 μm.

### (2) Elastic Layer

The elastic layer according to the present invention is characterized in that the storage elastic modulus at 25 °C is in the range of 0.5 to 10.0 MPa. Further, when the loss tangents of the elastic layer and the optical film according to the present invention are defined as tan δ₁ and tan δ₂, respectively, the value of the ratio of the loss tangents (tan δ₁/tan δ₂) satisfies the above Formula (1).

The elastic layer according to the present invention is not particularly limited as long as the storage elastic modulus at 25 °C is in a range of 0.5 to 10.0 MPa and the loss tangents satisfies the above Formula (1). Provided that the elastic layer according to the present invention is preferably made of an adhesive. Hereinafter, an adhesive suitably used will be described.

The elastic layer according to the present invention may have a form that can be rolled up like a film or a form of a coating layer. The coating layer is formed by applying the adhesive onto the adjacent layer, and then curing the adhesive.

The adhesive is not particularly limited as long as the storage elastic modulus of the produced elastic layer at 25 °C is in a range of 0.5 to 10.0 MPa and the loss tangents satisfies the above Formula (1). Examples of the adhesive include a rubber-based adhesive; acrylic adhesive; silicone-based adhesive; urethane-based adhesive; vinyl alkyl ether-based adhesive; polyvinyl alcohol-based adhesive; polyvinylpyrrolidone-based adhesive; polyacrylamide adhesive; and cellulose-based adhesive. Among these, an acrylic adhesive is preferable. The acrylic adhesive has excellent transparency and excellent adhesive properties (adhesion, cohesion, and bonding properties). In addition, weather resistance, heat resistance, and the like are excellent.

Note that the term “acrylic adhesive” as used herein refers to an adhesive containing an acrylic polymer as a base polymer.

### (2. 1) Configuration of Elastic Layer (Ultraviolet Curable Acrylic Adhesive)

The elastic layer formed of the acrylic adhesive is preferably, for example, a layer formed by ultraviolet curing (ultraviolet polymerization) of an ultraviolet curable acrylic adhesive. Note that ultraviolet curing (ultraviolet polymerization) of the ultraviolet curable acrylic adhesive generates a (meth)acrylic polymer.

The “ultraviolet curable acrylic adhesive” preferably contains a monomer component containing an alkyl (meth)acrylate or a partial polymer of the monomer component, an ultraviolet absorber, a photopolymerization initiator having an absorption band at a wavelength of 400 nm or more, and the like.

### (2. 1. 1) Monomer Component

The ultraviolet curable acrylic adhesive contains, as a base polymer, a (meth)acrylic polymer obtained by ultraviolet curing (ultraviolet polymerization) of a monomer component containing an acrylate or a partial polymer of the monomer component.

The alkyl (meth)acrylate contained in the monomer component and other monomers that may be contained are described below. The other monomer which may be contained is preferably a monofunctional monomer, but may be a polyfunctional monomer.

### (2. 1. 1.1) Alkyl(Meth)Acrylate

In the present invention, the term “(meth)acrylic” refers to acrylic and methacrylic, and is a generic term thereof. Furthermore, the term “alkyl (meth)acrylate” refers to alkyl acrylate and alkyl methacrylate, and is a generic term therefor.

The alkyl (meth)acrylate according to the present invention is preferably an alkyl (meth)acrylate having a linear or branched alkyl group having 1 to 24 carbon atoms at the ester terminus.

These may be used alone or in combination of two or more kinds thereof.

Examples of the alkyl (meth)acrylate include alkyl (meth)acrylates having a branched alkyl group having 4 to 9 carbon atoms. Specific examples thereof include n-butyl (meth)acrylate, sec-butyl (meth)acrylate, tert-butyl (meth)acrylate, isobutyl (meth)acrylate, n-pentyl (meth)acrylate, isopentyl (meth)acrylate, isohexyl (meth)acrylate, isoheptyl (meth)acrylate, 2-ethylhexyl (meth)acrylate, isooctyl (meth)acrylate, and isononyl (meth)acrylate.

These may be used alone or in combination of two or more kinds thereof.

The content of the alkyl (meth)acrylate having an alkyl group having 1 to 24 carbon atoms at the ester terminus is preferably 40% by mass or more based on the total mass of the monomer components. In addition, the content is more preferably 50% by mass or more, and even more preferably 60% by mass or more.

### (2. 1. 1.2) Other Monomer Components

Examples of the monofunctional copolymerizable monomer (monofunctional monomer) other than alkyl (meth)acrylate include cyclic nitrogen containing monomers. The cyclic nitrogen-containing monomer is not particularly limited as long as it has a polymerizable functional group having an unsaturated double bond, such as a (meth)acryloyl group or a vinyl group, and has a cyclic nitrogen structure. The cyclic nitrogen structure preferably has a nitrogen atom in the cyclic structure.

Examples of the cyclic nitrogen-containing monomer include lactam-based vinyl monomers such as N-vinyl-2-pyrrolidone, N-vinyl-8-caprolactam, and methylvinylpyrrolidone; and vinyl-based monomers having a nitrogen-containing heterocycle such as vinylpyridine, vinylpiperidone, vinylpyrimidine, vinylpiperazine, vinylpyrazine, vinylpyrrole, vinylimidazole, vinyloxazole, and vinylmorpholine. Other examples include (meth)acrylic monomers containing a heterocycle such as a morpholine ring, a piperidine ring, a pyrrolidine ring, and a piperazine ring.

Specific examples include N-acryloylmorpholine, N-acryloylpiperidine, N-methacryloylpiperidine, and N-acryloylpyrrolidine.

Among these, a lactam-based vinyl monomer is preferable.

The content of the cyclic nitrogen-containing monomer is preferably 0.5 to 50% by mass, more preferably 0.5 to 40% by mass, and still more preferably 0.5 to 30% by mass, relative to the total mass of the monomer components.

Examples of the monofunctional monomer include hydroxy group-containing monomers. The hydroxy group-containing monomer is not particularly limited as long as it has a polymerizable functional group having an unsaturated double bond, such as a (meth)acryloyl group or a vinyl group, and has a hydroxy group.

Examples of the hydroxy group containing monomer include hydroxyalkyl (meth)acrylates such as 2-hydroxyethyl (meth)acrylate, 2-hydroxypropyl (meth)acrylate, 2-hydroxybutyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate; hydroxyalkylcycloalkane (meth)acrylates such as (4-hydroxymethylcyclohexyl) methyl (meth)acrylate; and the like. Other examples include hydroxyethyl (meth)acrylamide, allyl alcohol, 2-hydroxyethyl vinyl ether, 4-hydroxybutyl vinyl ether, diethylene glycol monovinyl ether, and the like. Among these, hydroxyalkyl (meth)acrylate is preferable.

These may be used alone or in combination of two or more kinds thereof.

The content of the hydroxy group containing monomer is preferably in a range of 1 to 30% by mass, more preferably in a range of 2 to 27% by mass, and still more preferably in a range of 3 to 25% by mass, relative to the total mass of the monomer components. When the content is within the above range, a decrease in the adhesive force of the elastic layer can be suppressed. In addition, an increase in viscosity and gelation of the obtained adhesive can be suppressed.

Other examples of the monofunctional monomer include a carboxy group containing monomer and a monomer having a cyclic ether group.

The carboxy group-containing monomer is not particularly limited as long as it has a polymerizable functional group having an unsaturated double bond, such as a (meth)acryloyl group or a vinyl group, and has a carboxy group.

Examples of the carboxy group containing monomer include (meth)acrylic acid, carboxyethyl (meth)acrylate, carboxypentyl (meth)acrylate, itaconic acid, maleic acid, fumaric acid, crotonic acid, and isocrotonic acid. Furthermore, itaconic acid or maleic acid may be an anhydride thereof.

Among these, acrylic acid or methacrylic acid is preferable, and acrylic acid is more preferable.

These may be used alone or in combination of two or more kinds thereof.

The monomer having a cyclic ether group is not particularly limited as long as it has a polymerizable functional group having an unsaturated double bond, such as a (meth)acryloyl group or a vinyl group, and has a cyclic ether group, such as an epoxy group or an oxetane group.

Examples of the epoxy group containing monomer include glycidyl (meth)acrylate, 3,4-epoxycyclohexylmethyl (meth)acrylate, and 4-hydroxybutyl (meth)acrylate glycidyl ether. Examples of the oxetane group containing monomer include 3-oxetanylmethyl (meth)acrylate, 3-methyl-oxetanylmethyl (meth)acrylate, 3-ethyl-oxetanylmethyl (meth)acrylate, 3-butyl-oxetanylmethyl (meth)acrylate, and 3-hexyl-oxetanylmethyl (meth)acrylate.

These may be used alone or in combination of two or more kinds thereof.

### Cut.

The content of the carboxy group containing monomer or the monomer having a cyclic ether group is preferably 30% by mass or less, more preferably 27% by mass or less, and still more preferably 25% by mass or less, based on the total mass of the monomer components.

Examples of other monofunctional monomers include alkyl (meth)acrylates represented by CH₂═C(R¹)COOR² (where R¹ represents a hydrogen atom or a methyl group, and R² represents a substituted alkyl group or cyclic cycloalkyl group having 1 to 3 carbon atoms).

Examples of the alkyl (meth)acrylate represented by CH₂═C(R¹)COOR² include phenoxyethyl (meth)acrylate, benzyl (meth)acrylate, cydohexyl (meth)acrylate, 3,3,5-trimethylcyclohexyl (meth)acrylate, isobornyl (meth)acrylate, and the like.

These may be used alone or in combination of two or more kinds thereof.

The content of the alkyl (meth)acrylate represented by CH₂═C(R¹)COOR² is preferably 50% by mass or less, more preferably 45% by mass or less, and even more preferably 40% by mass or less, relative to the total mass of the monomer components.

Examples of other monofunctional monomers include vinyl acetate, vinyl propionate, styrene, α-methylstyrene; glycol-based acrylic ester monomers such as polyethylene glycol (meth)acrylate, polypropylene glycol (meth)acrylate, methoxyethylene glycol (meth)acrylate, and methoxypolypropylene glycol (meth)acrylate; acrylic ester monomers such as tetrahydrofurfuryl (meth)acrylate, fluorine (meth)acrylate, silicone (meth)acrylate, and 2-methoxyethyl acrylate; amide group-containing monomers, amino group-containing monomers, imide group-containing monomers, N-acryloylmorpholine, and vinyl ether monomers. Other examples include monomers having a cyclic structure, such as terpene (meth)acrylate and dicyclopentanyl (meth)acrylate.

Furthermore, examples of other monofunctional monomers include silane based monomers containing a silicon atom.

Examples of the silane-based monomer include 3-acryloxypropyltriethoxysilane, vinyltrimethoxysilane, vinyltriethoxysilane, 4-vinylbutyltrimethoxysilane, 4-vinylbutyltriethoxysilane, 8-vinyloctyltrimethoxysilane, 8-vinyloctyltriethoxysilane, 10-methacryloyloxydecyltrimethoxysilane, 10-acryloyloxydecyltrimethoxysilane, 10-methacryloyloxydecyltriethoxysilane, 10-acryloyloxydecyltriethoxysilane and the like.

As the other monomers, in addition to the monofunctional monomer exemplified above, a polyfunctional monomer may be contained as necessary from the viewpoint of adjusting the cohesive force of the elastic layer.

The polyfunctional monomer is not particularly limited as long as it is a monomer having at least two polymerizable functional groups having an unsaturated double bond, such as a (meth)acryloyl group or a vinyl group.

Examples of the polyfunctional monomer include ester compounds of polyhydric alcohols and (meth)acrylic acid such as (poly)ethylene glycol di(meth)acrylate, (poly) propylene glycol di(meth)acrylate, neopentyl glycol di(meth)acrylate, pentaerythritol di(meth)acrylate, pentaerythritol tri(meth)acrylate, dipentaerythritol hexa(meth)acrylate, 1,2-ethylene glycol di(meth)acrylate, 1,6-hexanediol di(meth)acrylate, 1,12-dodecanediol di(meth)acrylate, trimethylolpropane tri(meth)acrylate, and tetramethylolmethane tri(meth)acrylate; allyl (meth)acrylate, vinyl (meth)acrylate, divinylbenzene, epoxy acrylate, polyester acrylate, urethane acrylate, butyl di(meth)acrylate, and hexyl di(meth)acrylate.

Among these, trimethylolpropane tri(meth)acrylate, hexanediol di(meth)acrylate, or dipentaerythritol hexa(meth)acrylate is preferable.

These may be used alone or in combination of two or more kinds thereof.

The content of the polyfunctional monomer varies depending on the molecular weight, the number of functional groups, and the like, but is preferably 3% by mass or less, more preferably 2% by mass or less, and still more preferably 1% by mass or less, relative to the total mass of the monofunctional monomers. Further, the content of the polyfunctional monomer is preferably 0.001% by mass or more. When the content is within the above range, the adhesive force of the elastic layer can be improved.

The monomer components may include partially polymerized products of the above-described monomer components.

### (2. 1. 2) Ultraviolet Absorber

The ultraviolet-curable acrylic adhesive according to the present invention preferably contains an ultraviolet absorber. When the ultraviolet absorber is contained, the influence of ultraviolet rays on the internal module (display unit) can be reduced.

The ultraviolet absorber is not particularly limited. Examples thereof include a triazine-based ultraviolet absorber, a benzotriazole-based ultraviolet absorber, benzophenone-based ultraviolet absorber, an oxybenzophenone-based ultraviolet absorber, a salicylic acid ester-based ultraviolet absorber, and a cyanoacrylate-based ultraviolet absorber.

These may be used alone or in combination of two or more kinds thereof.

Among these, a triazine-based ultraviolet absorber is preferable, and a triazine-based ultraviolet absorber having two or less hydroxy groups in one molecule is more preferable. Furthermore, the ultraviolet absorber is preferably a benzotriazole-based ultraviolet absorber, and more preferably a benzotriazole-based ultraviolet absorber having one benzotriazole skeleton in one molecule. These UV absorbers are suitably used because of their good solubility in monomer components and their high capability of absorbing UV rays at a wavelength of around 380 nm.

The content of the ultraviolet absorber is preferably in a range of 0.1 to 5% by mass and more preferably in a range of 0.5 to 3% by mass with respect to the total mass of the monomer components. When the content is within the above range, ultraviolet absorbing functions can be sufficiently given to the elastic layer, and interference with ultraviolet curing (UV polymerization) can be suppressed.

### (2. 1. 3) Photopolymerization Initiator

The UV curable acrylic adhesive according to the present invention preferably contains a photopolymerization initiator (A) having an absorption band at a wavelength of 400 nm or more (hereinafter, also simply referred to as “photopolymerization initiator (A)”).

In general, in a case where an ultraviolet curable adhesive contains an ultraviolet absorber, when ultraviolet curing (ultraviolet polymerization) is performed, ultraviolet rays are absorbed by the ultraviolet absorber, and the ultraviolet curable adhesive cannot be sufficiently polymerized. However, since the ultraviolet curable acrylic adhesive according to the present invention has a photopolymerization initiator having an absorption band at a wavelength of 400 nm or more, it can be sufficiently polymerized despite the inclusion of an ultraviolet absorber.

Examples of the photopolymerization initiator (A) include bis(2,4,6-trimethylbenzoyl)-phenylphosphineoxide (a commercially available product is, for example, “Omnirad® 819” (manufactured by IGM Resins B. V.)). Other examples include 2,4,6-trimethylbenzoyldiphenyl-phosphineoxide (a commercially available product is, for example, “Omnirad® TPO H” (manufactured by IGM Resins B. V.)).

The photopolymerization initiators (A) may be used alone or in combination of two or more kinds thereof.

The content of the photopolymerization initiator (A) is not particularly limited, but is preferably smaller than the content of the ultraviolet absorber. The content is preferably in a range of 0.005 to 1% by mass and more preferably in a range of 0.02 to 0.5% by mass relative to the total mass of the monomer components. When the content is within the above range, ultraviolet curing (ultraviolet polymerization) can sufficiently progress.

In addition, the UV curable acrylic adhesive according to the present invention preferably contains a photopolymerization initiator (B) having an absorption band at a wavelength of less than 400 nm (hereinafter, also simply referred to as “photopolymerization initiator (B)”). The photopolymerization initiator (B) preferably does not have an absorption band at a wavelength of 400 nm or longer.

The photopolymerization initiator (B) is not particularly limited as long as it generates a radical by ultraviolet light to initiate photopolymerization and has an absorption band at a wavelength of less than 400 nm. A commonly used photopolymerization initiator can be suitably used as the photopolymerization initiator (B). Examples thereof include a benzoin ether-based photopolymerization initiator, an acetophenone-based photopolymerization initiator, an α-ketol-based photopolymerization initiator, a photoactive oxime-based photopolymerization initiator, a benzoin-based photopolymerization initiator, a benzyl-based photopolymerization initiator, a benzophenone-based photopolymerization initiator, a ketal-based photopolymerization initiator, a thioxanthone-based photopolymerization initiator, and an acylphosphine oxide-based photopolymerization initiator.

The photopolymerization initiator (B) may be used alone or in combination of two or more kinds thereof.

The content of the photopolymerization initiator (B) is preferably in a range of 0.005 to 0.5% by mass and more preferably in the range of 0.02 to 0.1% by mass relative to the total mass of the monomer components.

In the present invention, the photopolymerization initiator (B) is added first to the monomer components. Next, it is preferable that the photopolymerization initiator (A) and the ultraviolet absorber are added to the partially polymerized product (prepolymer composition) of the monomer components partially polymerized by irradiation with ultraviolet rays, and ultraviolet curing (ultraviolet polymerization) is performed. When the photopolymerization initiator (A) is added to the partially polymerized product (prepolymer composition) of the monomer components partially polymerized by irradiation with ultraviolet rays, the photopolymerization initiator (A) is preferably added after being dissolved in monomer.

### (2. 1. 4) Others

The ultraviolet-curable acrylic adhesive according to the present invention may further contain a silane coupling agent, a crosslinking agent, and the like.

Examples of the silane coupling agent include epoxy group-containing silane coupling agents such as 3-glycidoxypropyltrimethoxysilane, 3-glycidoxypropyltriethoxysilane, 3-glycidoxypropylmethyldiethoxysilane, and 2-(3,4-epoxycyclohexyl)ethyltrimethoxysilane; amino group-containing silane coupling agents such as 3-aminopropyltrimethoxysilane, N-2-(aminoethyl)-3-aminopropylmethyldimethoxysilane, 3-triethoxysilyl-N-(1,3-dimethylbutylidene) propylamine, and N-phenyl-γ-aminopropyltrimethoxysilane; (meth)acrylic group-containing silane coupling agents such as 3-acryloxypropyltrimethoxysilane and 3-methacryloxypropyltriethoxysilane; and isocyanate group-containing silane coupling agents such as 3-isocyanatepropyltriethoxysilane.

The content of the silane coupling agent is preferably 1% by mass or less, more preferably in a range of 0.01 to 1% by mass, and still more preferably in a range of 0.02 to 0.6% by mass, relative to the total mass of the monomer components.

Examples of the crosslinking agent include crosslinking agents such as isocyanate-based crosslinking agent, epoxy-based crosslinking agent, silicone-based crosslinking agent, oxazoline-based crosslinking agent, aziridine-based crosslinking agent, silane-based crosslinking agent, alkyl etherified melamine-based crosslinking agent, metal chelate-based crosslinking agent, and peroxide-based crosslinking agent. Among these, an isocyanate-based crosslinking agent is preferable.

These may be used alone or in combination of two or more kinds thereof.

The isocyanate-based crosslinking agent is a compound having two or more isocyanate groups (including an isocyanate regenerative functional group in which an isocyanate group is temporarily protected with a blocking agent, by multimerization, or the like) in one molecule. Examples of the isocyanate-based crosslinking agent include aromatic isocyanates such as tolylene diisocyanate and xylene diisocyanate; alicyclic isocyanates such as isophorone diisocyanate; and aliphatic isocyanates such as hexamethylene diisocyanate.

The content of the crosslinking agent is preferably 5% by mass or less, more preferably within a range of 0.01 to 5% by mass, still more preferably within a range of 0.01 to 4% by mass, and particularly preferably within a range of 0.02 to 3% by mass, relative to the total mass of the monomer components.

The ultraviolet-curable acrylic adhesive according to the present invention may appropriately contain, in addition to the above-described components, other additives depending on the application. Examples of additives include tackifiers (e.g., rosin derivative resins, polyterpene resins, petroleum resins, oil-soluble phenolic resins, etc. that are solid, semi-solid, or liquid at room temperature); fillers such as hollow glass balloons; plasticizers; antistaling agents; and antioxidants.

The ultraviolet-curable acrylic adhesive according to the present invention is preferably adjusted to a viscosity suitable for application. The viscosity can be adjusted, for example, by adding various polymers such as a thickening additive, a polyfunctional monomer, and the like, or by partially polymerizing monomer components in the ultraviolet-curable acrylic adhesive. The partial polymerization may be performed before or after the addition of various polymers such as thickening additives, polyfunctional monomers, and the like.

The viscosity of the ultraviolet curable acrylic adhesive according to the present invention varies depending on the content of the additives and the like. Therefore, the polymerization rate in the case of partially polymerizing the monomer components in the ultraviolet-curable acrylic adhesive cannot be uniquely determined. However, as a guide, the polymerization rate is preferably 20% or less, more preferably within a range of 3 to 20%, and still more preferably within a range of 5 to 15%.

When the polymerization rate is 20% or less, the viscosity can be adjusted to a viscosity suitable for application.

### (2.2) Method of Producing Elastic Layer

The elastic layer can be produced by applying the ultraviolet-curable acrylic adhesive onto the adjacent layer, and irradiating the adhesive with ultraviolet rays to perform ultraviolet curing (ultraviolet polymerization). Alternatively, a film-like elastic layer can be produced by applying the ultraviolet-curable acrylic adhesive onto the base material and irradiating the adhesive with ultraviolet light to cure the adhesive with ultraviolet light (ultraviolet polymerization).

The base material is not particularly limited, and examples thereof include a release film and a transparent resin film.

Examples of the release film include release resin films such as polyethylene, polypropylene, polyethylene terephthalate, and polyester films; porous materials such as paper, cloth, and nonwoven fabric; and thin materials such as nets, foam sheets, metal foils, and laminates thereof. Among these, a resin film is preferable from the viewpoint of excellent surface smoothness.

Examples of the release resin film include polyethylene film, polypropylene film, polybutene film, polybutadiene film, polymethylpentene film, polyvinyl chloride film, vinyl chloride copolymer film, polyethylene terephthalate film, polybutylene terephthalate film, polyurethane film, and ethylene-vinyl acetate copolymer film.

The thickness of the release film is preferably in a range of 5 to 200 μm, and preferably in a range of 5 to 100 μm.

It is preferable that the release film is subjected to mold release treatment with a silicone-based, fluorine-based, long-chain alkyl-based or fatty acid amide-based mold release agent if necessary. In addition, it is preferable to perform an antifouling treatment with silica powder or the like. In addition, an antistatic treatment of a coating type, a kneading type, a vapor deposition type, or the like may be performed. In particular, as a release treatment with a silicone-based, fluorine-based, or long-chain alkyl-based release agent is performed, the film-like elastic layer is easily peeled off.

The transparent resin film is not particularly limited, but it is preferable that the transparent resin film has transparency and is formed of a single-layer film.

Examples of the transparent resin film include polyester resin such as polyethylene terephthalate and polyethylene naphthalate, acetate resin, polyethersulfone resin, polycarbonate-based resin, polyamide-based resin, polyimide-based resin, polyolefin-based resin, (Meth)acrylic resin, polyvinyl chloride-based resin, polyvinylidene chloride-based resin, polystyrene-based resin, polyvinyl alcohol-based resin, polyarylate resin, and polyphenylene sulfide-based resin.

Among these, a polyester-based resin, a polyimide-based resin, or a polyethersulfone-based resin is preferable.

The thickness of the transparent resin film is preferably in a range of 2 to 200 μm, and more preferably in a range of 20 to 188 μm.

The method of applying the ultraviolet-curable acrylic adhesive is not particularly limited, and a conventionally known method can be used. Examples of the application method include a roll coating method, a kiss roll coating method, a gravure coating method, a reverse coating method, a roll brush method, a spray coating method, a dip roll coating method, a bar coating method, a knife coating method, an air knife coating method, a curtain coating method, a lip coating method, and a die coater method.

The illuminance of the ultraviolet rays with which the ultraviolet-curable acrylic adhesive is irradiated is preferably in a range of 5 to 200 mW/cm². When the illuminance of the ultraviolet rays is 5 mW/cm² or more, the polymerization time can be shortened and excellent producibility can be obtained. In addition, when the illuminance of ultraviolet rays is 200 mW/cm² or less, a photopolymerization initiator can be prevented from being rapidly consumed. As a result, the polymerization sufficiently proceeds, and a polymer ((meth)acryl-based polymer) having a high molecular weight is obtained. This makes it possible to provide an elastic layer having excellent holding power particularly at high temperature.

The accumulated amount of ultraviolet rays is preferably within a range of 100 to 5000 mJ/cm².

The ultraviolet lamp used in the present invention is not particularly limited, but is preferably an LED lamp. Since an LED lamp is a lamp that emits less heat than other UV lamps, it is possible to suppress a temperature increase during ultraviolet curing of the ultraviolet-curable acrylic adhesive. Thus, a polymer having a high molecular weight can be obtained, an elastic layer having sufficient cohesive strength can be obtained, and the holding power at high temperature can be increased when the elastic layer is formed into an adhesive sheet.

As the ultraviolet lamp, a plurality of ultraviolet lamps may be used in combination. In addition, as an irradiation method, ultraviolet rays may be intermittently emitted, and a light period in which ultraviolet rays are emitted and a dark period in which ultraviolet rays are not emitted may be provided.

The final polymerization rate of the monomer components in the ultraviolet-curable acrylic adhesive is preferably 90% or more, more preferably 95% or more, and still more preferably 98% or more.

The peak wavelength of the ultraviolet rays with which the ultraviolet-curable acrylic adhesive is irradiated are preferably within a range of 200 to 500 nm, and more preferably within a range of 300 to 450 nm. When the peak wavelength of the ultraviolet rays is 500 nm or less, the photopolymerization initiator is decomposed, and a polymerization reaction starts. In addition, when the peak wavelength of the ultraviolet ray is 200 nm or more, cutting of the polymer chain can be suppressed, and sufficient adhesiveness can be obtained.

Since the polymerization reaction tends to be inhibited by oxygen in the air, it is preferable to block oxygen. Examples of the method for blocking oxygen include a method of producing a release film or the like on the application layer of the ultraviolet-curable acrylic adhesive, a method of performing a polymerization reaction under a nitrogen atmosphere, and the like. Examples of the release film include the above-described release film.

### (2.3) Physical Properties of Elastic Layer

The storage elastic modulus of the elastic layer at 25 °C is preferably in a range of 0.5 to 10.0 MPa and more preferably in a range of 1.2 to 8.0 MPa from the viewpoint of achieving both impact resistance and flexibility.

The loss tangent (tan δ₁) of the elastic layer at 25 °C is not particularly limited as long as it satisfies the relationship of the above Formula (1), but it is preferably in a range of 0.01 to 1.5, more preferably in a range of 0.1 to 1.5.

The storage elastic modulus and the loss tangent (tan δ₁) of the elastic layer at 25 °C can be adjusted by appropriately selecting the types and the contents of the materials (the monomer component, the ultraviolet absorber, the photopolymerization initiator, and the like), the irradiation conditions of the ultraviolet rays, and the like.

The storage elastic modulus and the loss tangent of the elastic layer at 25 °C can be measured with a viscoelasticity measuring apparatus “ARES-G2” (manufactured by TA Instruments Japan Inc.) under the following test conditions.
Test Conditions (dynamic viscoelasticity test)
Tester: Viscoelasticity measuring apparatus “ARES G2” (manufactured by TA Instruments Japan Inc.)
Deformation method: Rotation
Temperature range: −50 to 100 °C.
Frequencies: 1 Hz
Displacement: Strain 0.05%
Sample size (e.g., form): φ8 mm, thickness about 1 mm

Distance between chucks: Automatically variable so that the load is 10 g (approximately equal to the sample thickness).

The thickness of the elastic layer is preferably in a range of 2 to 60 μm, more preferably in a range of 2 to 20 μm, and still more preferably in a range of 2 to 15 μm, from the viewpoint of further thinning the laminate to be finally obtained.

The weight average molecular weight (Mw) of the resin material (e.g.; (meth)acryl-based polymer) used in the elastic layer is preferably in a range of 100,000 to 5,000,000 and more preferably in a range of 200,000 to 1,000,000 from the viewpoint of controlling the loss tangent (tan δ₁).

The weight average molecular weight (Mw) of the resin material used in the elastic layer is preferably smaller than the weight average molecular weight (Mw) of the resin material used in the optical film described later.

Thus, the effect of the present invention can be more efficiently obtained.

The weight-average molecular weight (Mw) of the resin material can be measured with gel permeation chromatography “HLC8220GPC” (manufactured by Tosoh Corporation) and columns “TSK-GEL G6000”, “HXL-G5000”, “HXL-G5000”, “HXL-G4000”, and “HXL-G3000HXL” (all manufactured by Tosoh Corporation, in tandem).

The sample 20 mg±0.5 mg is dissolved in 10 mL of tetrahydrofuran and filtered through a 0.45 mm filter. Then, this liquid is injected into a column (at a temperature of 40 °C) by 100 mL injection, and measurement is performed with an RI detector at a temperature of 40 °C, and a value in terms of styrene is obtained.

The glass transition temperature (Tg) of the elastic layer is preferably 0 °C or lower, more preferably −10 °C or lower, and still more preferably −20 °C or lower, from the viewpoint of achieving both impact resistance and flexibility in a low-temperature environment.

The glass transition temperature (Tg) can be measured in accordance with JIS K 7121 (2012) using a differential scanning calorimeter (DSC).

### (3) Optical Film

The optical film according to the present invention is characterized by containing rubber particles. Further, when the loss tangents of the elastic layer and the optical film according to the present invention are defined as tan δ₁ and tan δ₂, respectively, the value of the ratio of the loss tangents (tan δ₁/tan δ₂) satisfies the above Formula (1).

The optical film according to the present invention is not particularly limited as long as the optical film contains rubber particles and the loss tangent satisfies the above Formula (1).

The optical film according to the present invention is preferably in a form of film that can be rolled up, but may be in a form of a coating layer formed by application on the adjacent layer.

### (3. 1) Configuration of Optical Film

The optical film according to the present invention is preferably formed into a film form by adding rubber particles such as a graft copolymer to a resin material.

From the viewpoint of flexibility, it is preferable to contain at least a combination of a thermoplastic (meth)acrylic resin and rubber particles of a graft copolymer.

Furthermore, the average light transmittance of the optical film according to the present invention in a wave length region of 380 to 780 nm (visible light region) is preferably 90% or less, and more preferably in a range of 39 to 89%. When the content is within the above range, a part of the functions of a polarizing plate can be imparted to the optical film, and specifically, external light reflection can be sufficiently suppressed. Furthermore, when the laminate is used as a cover glass unit of a display device, sufficient luminance can be obtained.

The average light transmittance in the visible light region can be adjusted by incorporating a coloring agent into the optical film.

### (3. 1. 1) Rubber Particles

In the present invention, the term “rubber particles” refers to particles containing resin exhibiting rubber elasticity at room temperature.

The optical film according to the present invention can be provided with toughness (flexibility) by the rubber particles. In addition, the loss tangent (tan δ₂) of the optical film can be appropriately adjusted.

The layer structure of the rubber particles according to the present invention may be a single-layer structure or a multi-layer structure. Furthermore, the resin exhibiting rubber elasticity at room temperature (hereinafter, also referred to as a “rubbery polymer”) is not particularly limited. The arrangement order of the monomers is also not particularly limited, and may be, for example, linear, comb-like (graft type), and branched (star type).

The rubber-like polymer may have a structure partially crosslinked with a crosslinking monomer.

In the present invention, the rubbery polymer is preferably a soft crosslinked polymer having a glass transition temperature (Tg) of 0 °C or lower from the viewpoint of exhibiting rubber elasticity at room temperature.

Examples of such a crosslinked polymer include a butadiene-based crosslinked polymer, a (meth)acryl-based crosslinked polymer, and an organosiloxane-based crosslinked polymer. Among these, from the viewpoint that the difference in refractive index from the thermoplastic (meth)acrylic resin is small and the transparency of the optical film is less likely to be impaired, a (meth)acrylic crosslinked polymer is preferable, and an acrylic crosslinked polymer is more preferable.

That is, the rubber particle according to the present invention is preferably a particle containing an acrylic crosslinked polymer (hereinafter, also referred to as “acrylic rubbery polymer”).

The content of the rubber particles is preferably in a range of 10 to 80% by mass with respect to the total mass of the optical film. When the content is within the above range, the optical film has appropriate hardness and the optical film can obtain a desired loss tangent (tan δ₂).

### (3. 1. 1. 1) Configuration of Rubber Particles

As described above, the rubber particle according to the present invention preferably contains an acrylic rubbery polymer. Hereinafter, for the purpose of description, the acrylic rubbery polymer is referred to as “acrylic rubbery polymer (a)”.

The acrylic rubbery polymer (a) is a crosslinked polymer having a structural unit derived from an acrylic acid ester as a main component.

Here, the expression “having as a main component” means that the content of the structural unit derived from an acrylate ester is within the range described below.

The acrylic rubbery polymer (a) is preferably a crosslinked polymer having a structural unit derived from an acrylic acid ester, a structural unit derived from another monomer copolymerizable therewith, and a structural unit derived from a polyfunctional monomer having two or more radically polymerizable groups (non-conjugated reactive double bonds) in one molecule.

The acrylic acid ester is preferably an alkyl acrylate ester in which the alkyl group has 1 to 12 carbon atoms, such as methyl acrylate (methyl acrylate), ethyl acrylate (ethyl acrylate), n-propyl acrylate (n-propyl acrylate), n-butyl acrylate (n-butyl acrylate), sec-butyl acrylate (sec-butyl acrylate), isobutyl acrylate (isobutyl acrylate), benzyl acrylate (benzyl acrylate), cyclohexyl acrylate (cyclohexyl acrylate), 2-ethylhexyl acrylate (2-ethylhexyl acrylate), or n-octyl acrylate (n-octyl acrylate).

These may be used alone or in combination of two or more kinds thereof.

The content of the structural unit derived from an acrylate ester is preferably in the range of 40 to 90% by mass and more preferably in the range of 50 to 80% by mass, relative to the total structural units constituting the acrylic rubbery polymer (a). When the content is within the above range, sufficient toughness can be given to the optical film.

Examples of the other monomer copolymerizable with the acrylic acid ester include methacrylic esters such as methyl methacrylate; styrenes such as styrene and methylstyrene; (meth)acrylonitriles; (meth)acrylamides; and (meth)acrylic acid. Among these, styrenes are preferable.

These may be used alone or in combination of two or more kinds thereof.

The content of the structural unit derived from the other monomer copolymerizable with the acrylic acid ester is preferably in a range of 5 to 55% by mass, more preferably in a range of 10 to 45% by mass, based on the total structural units constituting the acrylic rubbery polymer (a).

The multifunctional monomer having two or more radically polymerizable groups in one molecule includes, for example, allyl (meth)acrylate, triallyl cyanurate, triallyl isocyanurate, diallyl phthalate, diallyl malate, divinyl adipate, divinylbenzene, ethylene glycol di(meth)acrylate, diethylene glycol (meth)acrylate, triethylene glycol di(meth)acrylate, trimethylolpropane tri(meth)acrylate, tetramethylolmethane tetra(meth)acrylate, dipropylene glycol di(meth)acrylate, polyethylene glycol di(meth)acrylate.

The content of the structural unit derived from the polyfunctional monomer having two or more radically polymerizable groups in one molecule is preferably in a range of 0.05 to 10% by mass relative to the total structural units constituting the acrylic rubbery polymer (a). The content is more preferably within a range of 0.1 to 5% by mass. When the amount is 0.05% by mass or more, the degree of crosslinking of the obtained acrylic rubbery polymer (a) is easily increased, and the hardness and rigidity of the optical film are hardly impaired. In addition, when the content is 10% by mass or less, the toughness of the optical film is hardly impaired.

The composition of the monomers constituting the acrylic rubbery polymer (a) can be measured, for example, by the peak area ratio detected by pyrolysis GC-MS.

The glass transition temperature (Tg) of the acrylic rubbery polymer (a) is preferably 0 °C or lower, more preferably −10 °C or lower. When the glass transition temperature is 0 °C or lower, appropriate toughness can be given to the optical film. The glass transition temperature (Tg) of the acrylic rubbery polymer (a) can be measured by the same method as described above.

The glass transition temperature (Tg) of the acrylic rubbery polymer (a) can be adjusted by the composition of the acrylic rubbery polymer (a). For example, in order to lower the glass transition temperature (Tg), it is preferable to adjust the value of the mass ratio of the acrylate ester in which the alkyl group has 4 or more carbon atoms to the other monomer copolymerizable with the acrylate ester. The mass ratio is expressed by the mass of the acrylic acid ester/the mass of the other monomer copolymerizable with the acrylic acid ester. The value of the mass ratio is preferably 3 or more, and preferably within a range of 4 to 10.

The particle containing the acrylic rubbery polymer (a) may be a particle consisting of the acrylic rubbery polymer (a) alone. Further, it may be a particle having a hard layer comprising a hard crosslinked polymer (c) having a glass transition temperature (Tg) of 20 °C or higher and a soft layer comprising an acrylic rubbery polymer (a) disposed around the hard layer. Alternatively, the particles may be made of an acrylic graft copolymer obtained by polymerizing a mixture of monomers such as methacrylic acid esters in at least one stage in the presence of the acrylic rubbery polymer (a). The particle formed of the acrylic graft copolymer may be a core-shell type particle having a core part containing the acrylic rubbery polymer (a) and a shell part covering the core part.

### (Core Part)

The core part contains an acrylic rubbery polymer (a), and may further contain a hard crosslinked polymer (c) as necessary. That is, the core part may have a soft layer composed of the acrylic rubbery polymer (a) and a hard layer composed of the hard crosslinked polymer (c) arranged inside thereof.

Hereinafter, for the purpose of explanation, the hard crosslinked polymer is referred to as “crosslinked polymer (c)”.

The crosslinked polymer (c) is a crosslinked polymer containing a methacrylic acid ester as a main component. That is, the crosslinked polymer (c) is preferably a crosslinked polymer having a structural unit derived from a methacrylic acid ester, a structural unit derived from another monomer copolymerizable therewith, and a structural unit derived from a polyfunctional monomer having two or more radically polymerizable groups in one molecule.

The methacrylic acid ester is preferably an alkyl methacrylate. Examples of the alkyl methacrylate ester include those in which the alkyl acid in the above-mentioned alkyl acrylate ester is replaced with methacrylic acid.

Examples of the other monomer copolymerizable with a methacrylic acid ester include the same as the above-described other monomers copolymerizable with an acrylic acid ester.

Examples of the polyfunctional monomer having two or more radically polymerizable groups in one molecule include the same polyfunctional monomers as described above.

The content of the structural unit derived from an alkyl methacrylate is preferably in a range of 40 to 100% by mass relative to the total structural units constituting the crosslinked polymer (c). The content of the structural unit derived from another monomer copolymerizable with a methacrylic acid ester is preferably in a range of 60 to 0% by mass relative to the total structural units constituting the crosslinked polymer (c). The content of the structural unit derived from the polyfunctional monomer having two or more radically polymerizable groups in one molecule is preferably in a range of 0.01 to 10% by mass based on all the structural units constituting the crosslinked polymer (c).

### (Shell Part)

The shell part preferably contains a methacrylic polymer (b) (another polymer) having a structural unit derived from a methacrylic acid ester as a main component, which is graft-bonded to the acrylic rubbery polymer (a).

Hereinafter, for the sake of description, the methacrylic polymer having a structural unit derived from a methacrylic acid ester as a main component is referred to as a “methacrylic polymer (b)”.

Here, “having as a main component” means that the content of the structural units derived from a methacrylic acid ester is within a range described later.

The methacrylic acid ester forming the methacrylic polymer (b) is preferably an alkyl methacrylate having an alkyl group with 1 to 12 carbon atoms, such as methyl methacrylate.

These may be used alone or in combination of two or more kinds thereof.

The content of the methacrylic acid ester is preferably 50% by mass or more based on all the structural units constituting the methacrylic polymer (b). When the content of the methacrylic acid ester is 50% by mass or more, compatibility with a methacrylic resin having a structural unit derived from methyl methacrylate as a main component is easily obtained. From the above viewpoint, the content of the methacrylic acid ester is more preferably 70% by mass or more based on the total structural units constituting the methacrylic polymer (b).

The methacrylic polymer (b) may further have a structural unit derived from another monomer copolymerizable with a methacrylic acid ester. Examples of the other copolymerizable monomer include acrylic acid esters such as methyl acrylate (methyl acrylate), ethyl acrylate (ethyl acrylate), and n-butyl acrylate (n-butyl acrylate); (meth)acrylic monomers having an alicyclic, heterocyclic, or aromatic ring (ring-containing (meth)acrylic monomers) such as benzyl (meth)acrylate (benzyl (meth)acrylate), dicyclopentanyl (meth)acrylate (dicyclopentanyl (meth)acrylate), and phenoxyethyl (meth)acrylate (phenoxyethyl (meth)acrylate).

The content of the structural unit derived from another copolymerizable monomer is preferably 50% by mass or less and more preferably 30% by mass or less based on all the structural units constituting the methacrylic polymer (b).

The ratio (graft ratio) of the graft component in the rubber particle is preferably in a range of 10 to 250% by mass, more preferably in a range of 15 to 150% by mass. The graft ratio of 10% by mass or more means that the proportion of the graft component, i.e., the methacrylic polymer (b) containing a structural unit derived from a methacrylic acid ester as a main component, is moderately high. This makes it easy to increase the compatibility between the rubber particles and the methacrylic resin and makes the rubber particles even less likely to aggregate. In addition, the rigidity and the like of the film are hardly impaired. On the other hand, when the graft ratio is 250% by mass or less, the proportion of the acrylic rubbery polymer (a) does not become appropriately too small, and thus the toughness of the optical film is less likely to be impaired. In addition, the brittleness of the optical film can be sufficiently improved.

The graft ratio can be measured by the following method.
1) 2 g of core-shell type particles are dissolved in methylethyl ketone 50 ml. Using a centrifuge “CP60E” (manufactured by Koki Holdings Co., Ltd.), the solution is centrifuged at a rotational speed of 30000 rpm and a temperature of 12 °C for 1 hour to separate it into insoluble matter and soluble matter (the centrifugation operation is performed three times in total).
2) The graft ratio is calculated by applying the mass of the insoluble matter obtained to the following formula.

Graft ratio(% by mass)=[{(mass of methyl ethyl ketone−insoluble matter)−(mass of acrylic rubbery polymer(a))}/(mass of acrylic rubbery polymer(a))]×100 Formula:

### (3. 1. 1. 2) Physical Properties of Rubber Particles

The shape of the rubber particles is not particularly limited, but is preferably a shape close to a true sphere.

The term “shape close to a true sphere” refers to such a shape that an aspect ratio of a rubber particle is within a range of 1 to 2 when a cross section or a surface of the optical film is observed.

Since the rubber particles have a shape close to a true sphere as described above, sufficient resistance to deformation of the laminate due to contact with a roll during conveyance and deformation due to internal stress during winding can be obtained.

The average particle size of the rubber particles is preferably within a range of 100 to 400 nm. When the ratio is 100 nm or more, sufficient toughness and stress relaxation properties can be given to the optical film. In addition, when it is 400 nm or less, the transparency of the optical film is hardly impaired. From the above viewpoint, the average particle size of the rubber particles is more preferably in a range of 150 to 300 nm.

The average particle size of the rubber particles can be calculated by the following method.

The average particle size of the rubber particles can be measured as an average of the equivalent circle diameters of 100 particles obtained by SEM or TEM imaging of the surface or the cross section of the laminate. The equivalent circle diameter can be obtained by converting the projected area of the particle obtained by photographing into the diameter of a circle having the same area. At this time, rubber particles observed by SEM observation or TEM observation at a magnification of 5000 are used for the calculation of the average particle diameter.

### (3. 1. 2) Resin for Optical Film

The resin material is not particularly limited, and examples thereof include a thermoplastic (meth)acrylic resin and a cycloolefin resin.

The weight average molecular weight (Mw) of the resin material varies depending on the type of the resin material, but is preferably within a range of 5,000 to 4,000,000, for example. The weight average molecular weight (Mw) of the resin material can be measured by the above-described method.

### (3. 1. 2. 1) Thermoplastic (Meth)Acrylic Resin

The thermoplastic (meth)acrylic resin preferably has at least a structural unit derived from methyl methacrylate. Among these, the thermoplastic (meth)acrylic resin preferably further has a structural unit derived from phenylmaleimide, from the viewpoint of increasing the storage elastic modulus of the optical film and increasing the storability as a film which is a preferable form. In addition, from the viewpoint of improving brittleness due to having a structural unit derived from phenylmaleimide, it is more preferable to further have a structural unit derived from an alkyl acrylate ester.

That is, the thermoplastic (meth)acrylic resin preferably has a structural unit derived from methyl methacrylate, a structural unit derived from phenylmaleimide, and a structural unit derived from an alkyl acrylate ester.

The content of the structural unit derived from methyl methacrylate is preferably in a range of 50 to 95% by mass, and more preferably in a range of 70 to 90% by mass, with respect to the total structural units constituting the thermoplastic (meth)acrylic resin.

The structural unit derived from phenylmaleimide has a relatively rigid structure, and therefore can increase the storage elastic modulus of the optical film. The structural unit derived from phenylmaleimide has a relatively bulky structure and can have micro voids in which the graft copolymer (rubber particles) can move in the resin matrix. Thus, the graft copolymer (rubber particles) can be easily unevenly distributed in the surface layer portion of the optical film.

The content of the structural unit derived from phenylmaleimide is preferably in the range of 1 to 25% by mass relative to the total structural units constituting the thermoplastic (meth)acrylic resin. When the content of the structural unit derived from phenylmaleimide is 1% by mass or more, the storage elastic modulus of the optical film is easily increased, and when the content is 25% by mass or less, the brittleness of the optical film can be prevented from being excessively impaired. The content of the structural unit derived from phenylmaleimide is more preferably within a range of 7 to 15% by mass from the above-described viewpoints.

The structural unit derived from an alkyl acrylate ester can give moderate flexibility to the resin. Therefore, for example, by combining with the structural unit derived from phenylmaleimide, brittleness caused by the structural unit derived from phenylmaleimide can be improved.

The alkyl acrylate is preferably an alkyl acrylate having an alkyl moiety having 1 to 7 carbon atoms, preferably 1 to 5 carbon atoms.

Examples of the alkyl acrylate include methyl acrylate (methyl acrylate); ethyl acrylate (ethyl acrylate); propyl acrylate (propyl acrylate); butyl acrylate (butyl acrylate); 2-hydroxyethyl acrylate (2-hydroxyethyl acrylate); hexyl acrylate (hexyl acrylate); and 2-ethylhexyl acrylate (2-ethylhexyl acrylate).

The content of the structural unit derived from an alkyl acrylate is preferably in a range of 1 to 25% by mass with respect to the total structural units constituting the thermoplastic (meth)acrylic resin. When the content of the structural unit derived from an alkyl acrylate is 1% by mass or more, appropriate flexibility can be given to the thermoplastic (meth)acrylic resin. Thus, the brittleness of the optical film can be improved, and the optical film is less likely to be broken. When the content of the structural unit derived from an alkyl acrylate is 25% by mass or less, a decrease in the glass transition temperature (Tg) of the thermoplastic (meth)acrylic resin can be suppressed, and sufficient heat resistance and storage elastic modulus of the optical film can be obtained. From the above viewpoints, the content of the structural unit derived from an alkyl acrylate ester is more preferably within a range of 5 to 15% by mass.

The ratio of the structural unit derived from phenylmaleimide to the total amount of the structural unit derived from phenylmaleimide and the structural unit derived from an alkyl acrylate ester is preferably in the range of 20 to 70% by mass. When the ratio is 20% by mass or more, the storage elastic modulus of the optical film is easily increased, and when the ratio is 70% by mass or less, the brittleness of the optical film can be improved.

The glass transition temperature (Tg) of the thermoplastic (meth)acrylic resin is preferably 100 °C or higher, and more preferably within a range of 120 to 150 °C. When the content is within the above range, the heat resistance of the optical film can be enhanced. In order to adjust the Tg of the thermoplastic (meth)acrylic resin, for example, the content of the structural unit derived from phenylmaleimide or the structural unit derived from alkyl acrylate is preferably adjusted.

The weight average molecular weight (Mw) of the thermoplastic (meth)acrylic resin is preferably 100,000 or more, and more preferably 1,000,000 or more. When the weight average molecular weight (Mw) of the thermoplastic (meth)acrylic resin is 100,000 or more, the toughness of the optical film can be enhanced. Thus, the optical film can be prevented from being broken by the conveying tension during the conveyance of the film. Furthermore, since the storage elastic modulus of the optical film can be increased, winding deformation can be suppressed.

The weight average molecular weight (Mw) of the thermoplastic (meth)acrylic resin is more preferably in a range of 1,500,000 to 3,000,000 from the above-described viewpoints.

The weight average molecular weight (Mw) of the thermoplastic (meth)acrylic resin can be measured by the above-described method.

In the case of an optical film containing at least a thermoplastic (meth)acrylic resin and rubber particles, the content of the thermoplastic (meth)acrylic resin is preferably in a range of 5 to 95% by mass relative to the total mass of the optical film. In addition, the content is more preferably in the range of 10 to 60% by mass, even more preferably in a range of 10 to 50% by mass, and particularly preferably in a range of 10 to 40% by mass.

In the case of an optical film containing at least a thermoplastic (meth)acrylic resin and rubber particles, the content of the rubber particles is preferably in a range of 10 to 80% by mass relative to the total mass of the optical film. In addition, the content is more preferably in a range of 20 to 60% by mass and even more preferably in a range of 20 to 50% by mass. When the content is within the range described above, the size of the aggregate becomes sufficient and substantially uniform, and an optical film in which a foreign substance is unlikely to be incorporated thereinto and which has improved its optical properties and mechanical properties is obtained.

### (3. 1. 2. 2) Cycloolefin Resin

The cycloolefin resin is preferably a polymer of cycloolefin monomers or a copolymer of a cycloolefin monomer and another monomer copolymerizable with the cycloolefin monomer.

The cycloolefin monomer is preferably a cycloolefin monomer having a norbornene skeleton. Above all, a cycloolefin monomer having a structure represented by the following General Formula (A-1) or (A-2) is more preferable.

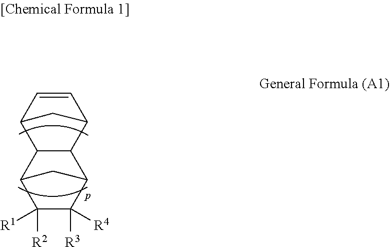

In General Formula (A-1), R¹ to R⁴ each independently represent hydrogen atoms, hydrocarbon groups having 1 to 30 carbon atoms, or polar groups. P represents an integer of 0 to 2. However, all of R¹ to R⁴ do not represent hydrogen atoms at the same time, R¹ and R² do not represent hydrogen atoms at the same time, and R³ and R⁴ do not represent hydrogen atoms at the same time.

In the General Formula (A-1), the hydrocarbon group having 1 to 30 carbon atoms represented by R¹ to R⁴ is, for example, preferably a hydrocarbon group having 1 to 10 carbon atoms, and more preferably a hydrocarbon group having 1 to 5 carbon atoms. The hydrocarbon group having 1 to 30 carbon atoms may further have a linking group containing, for example, a halogen atom, an oxygen atom, a nitrogen atom, a sulfur atom, or a silicon atom. Examples of such a linking group include divalent polar groups such as a carbonyl group, an imino group, an ether bond, a silyl ether bond, and a thioether bond. Examples of the hydrocarbon group having 1 to 30 carbon atoms include a methyl group, an ethyl group, a propyl group, and a butyl group.

In the General Formula (A-1), examples of the polar groups represented by R¹ to R⁴ include carboxy group; hydroxy group; alkoxy group; alkoxycarbonyl group; aryloxycarbonyl group; amino group; amide group; and cyano group. Among these, a carboxy group, a hydroxy group, an alkoxycarbonyl group, or an aryloxycarbonyl group is preferable. From the viewpoint of solubility during solution film formation, an alkoxycarbonyl group or an aryloxycarbonyl group is preferable.

From the viewpoint of enhancing heat resistance, p in the General Formula (A-1) is preferably 1 or 2. When p is 1 or 2, the obtained polymer becomes bulky, and the glass transition temperature is easily improved. In addition, it becomes possible to slightly respond to humidity, and it becomes easy to control the curl balance when used in a laminate.

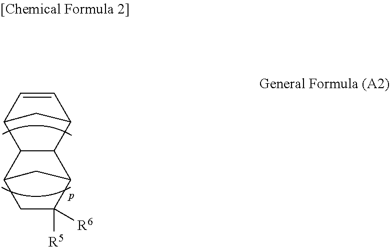

In the General Formula (A-2), R⁵ represents a hydrogen atom, a hydrocarbon group having 1 to 5 carbon atoms, or an alkylsilyl group having an alkyl group having 1 to 5 carbon atoms. R⁶ represents a carboxy group, a hydroxy group, an alkoxycarbonyl group, an aryloxycarbonyl group, an amino group, an amide group, a cyano group, or a halogen atom (a fluorine atom, a chlorine atom, a bromine atom, or an iodine atom). P represents an integer of 0 to 2.

R⁵ in the General Formula (A-2) is preferably a hydrocarbon group having 1 to 5 carbon atoms, and more preferably a hydrocarbon group having 1 to 3 carbon atoms.

R⁶ in the General Formula (A-2) is preferably a carboxy group, a hydroxy group, an alkoxycarbonyl group, or an aryloxycarbonyl group. Among these, an alkoxycarbonyl group or an aryloxycarbonyl group is more preferable from the viewpoint of solubility at the time of solution film formation.

In the above General Formula (A-2), p is preferably 1 or 2 from the viewpoint of enhancing heat resistance. When p is 1 or 2, the obtained polymer becomes bulky, and the glass transition temperature is easily improved.

From the viewpoint of improving solubility in an organic solvent, the cycloolefin monomer is preferably a cycloolefin monomer having a structure represented by the above General Formula (A-2). In general, when the symmetry of an organic compound is broken, the crystallinity of the organic compound is reduced and the solubility of the organic compound in an organic solvent is improved. Since R⁵ and R⁶ in the General Formula (A-2) are substituted on only one side of the carbon atoms constituting the ring with respect to the axis of symmetry of the molecule, the molecular symmetry is low. That is, since the cycloolefin monomer having the structure represented by the General Formula (A-2) has high solubility, it is suitable for producing an optical film by a solution casting method.

The content of the cycloolefin monomers having a structure represented by the General Formula (A-2) in the cycloolefin resin is preferably 70 mol % or more based on the total number of moles of all the cycloolefin monomers constituting the cycloolefin resin. In addition, the content is more preferably 80 mol % or more, and still more preferably 100 mol %. When the content of the cycloolefin monomers having the structure represented by the General Formula (A-2) is 70 mol % or more, the orientation property of the cycloolefin resin is enhanced and the phase difference (retardation) value tends to increase.

Hereinafter, specific examples of the cycloolefin monomer having a structure represented by the General Formula (A-1) are shown in Exemplary Compounds 1 to 14. Specific examples of the cycloolefin monomer having the structure represented by the General Formula (A-2) are shown in Exemplary Compounds 15 to 34.

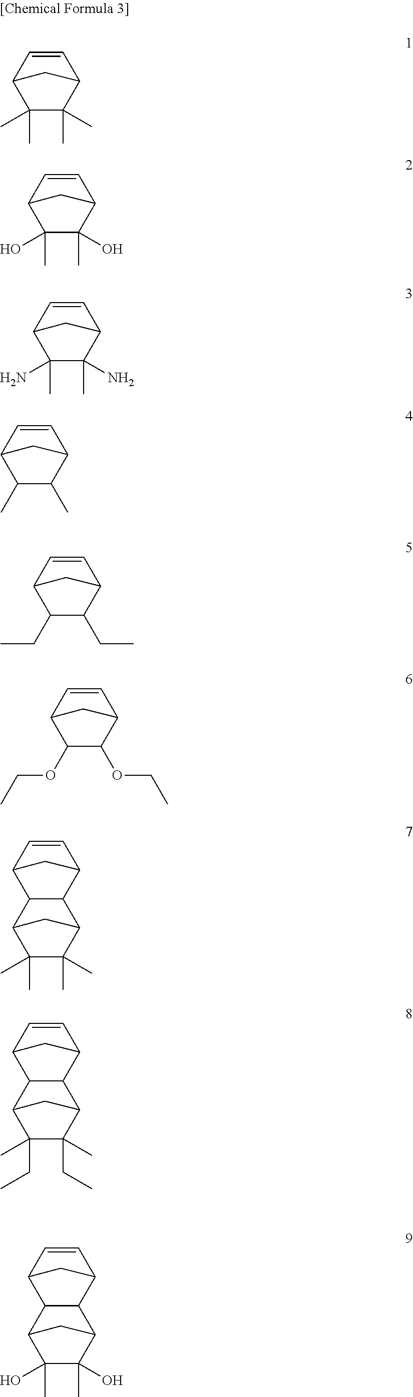

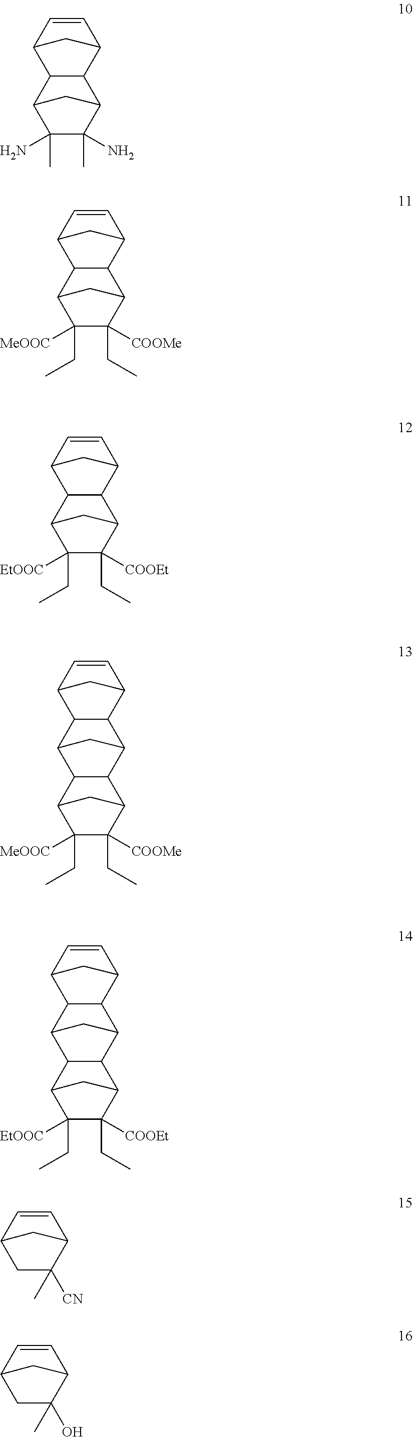

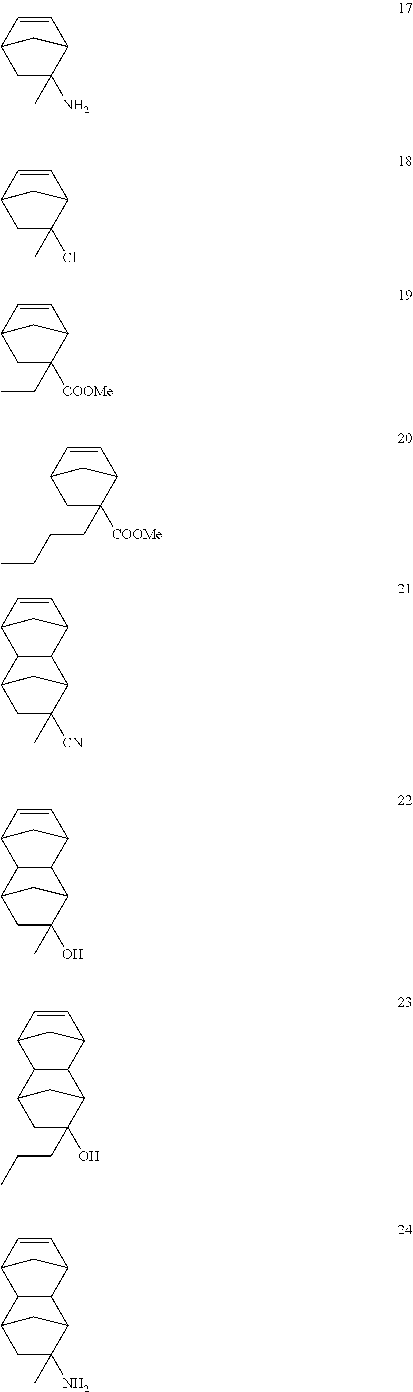

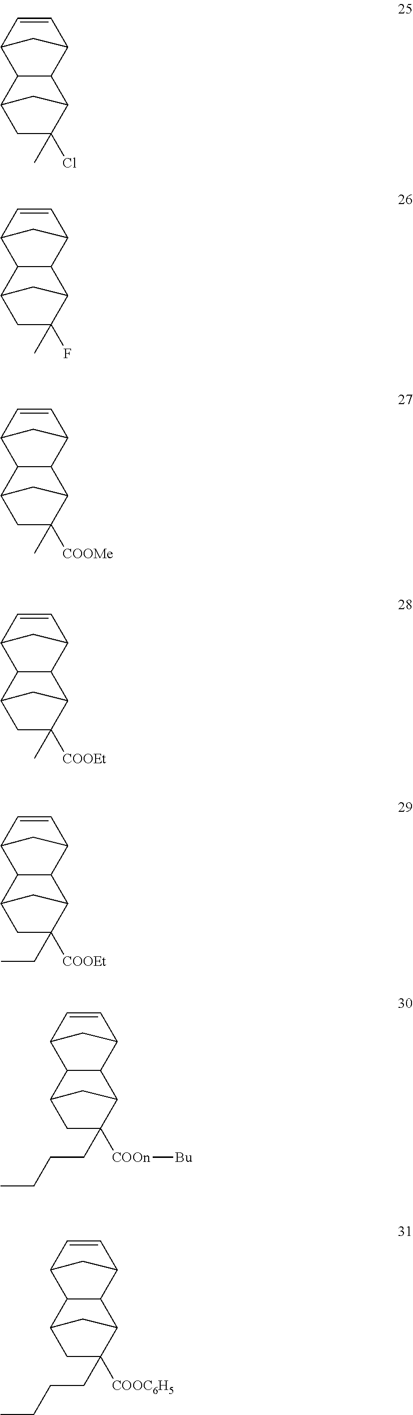

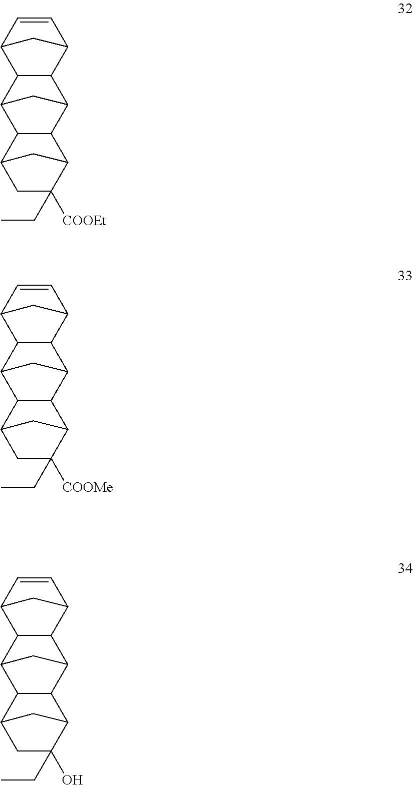

Examples of the copolymerizable monomer copolymerizable with the cycloolefin monomer include a copolymerizable monomer ring-opening copolymerizable with the cycloolefin monomer, and a copolymerizable monomer addition-copolymerizable with the cycloolefin monomer.

Examples of the copolymerizable monomer capable of ring-opening copolymerization include cycloolefins such as cyclobutene, cyclopentene, cycloheptene, cyclooctene and dicyclopentadiene.

Examples of the copolymerizable monomer capable of addition copolymerization include unsaturated double bond-containing compounds, vinyl-based cyclic hydrocarbon monomers, and (meth)acrylates. Examples of the unsaturated double bond-containing compound include olefin-based compounds having 2 to 12 (preferably 2 to 8) carbon atoms, for example, ethylene, propylene, butene, and the like. Examples of the vinyl-based cyclic hydrocarbon monomer include vinylcyclopentene-based monomers such as 4-vinylcyclopentene and 2-methyl-4-isopropenylcyclopentene. Examples of the (meth)acrylate include alkyl (meth)acrylates having 1 to 20 carbon atoms, such as methyl (meth)acrylate, 2-ethylhexyl (meth)acrylate, and cyclohexyl (meth)acrylate.

The content ratio of the cycloolefin monomer in the copolymer of the cycloolefin monomer and the copolymerizable monomer is preferably in a range of 20 to 80 mol % and preferably in a range of 30 to 70 mol % with respect to the sum of all the monomers constituting the copolymer.

As described above, the cycloolefin resin is a polymer obtained by homopolymerization or copolymerization of a cycloolefin monomer having a norbornene skeleton, preferably a cycloolefin monomer having a structure represented by the General Formula (A-1) or (A-2). Examples of such a polymer include the following.
1) Ring-opened copolymer of cycloolefin monomer
2) Ring-opened copolymer of cycloolefin monomer and copolymerizable monomer ring-opening copolymerizable therewith
3) Hydrogenated product of the above ring-opened (co)polymers of 1) and 2)
4) (Co)polymer obtained by cyclizing the above ring-opened (co)polymers of 1) and 2) by Friedel-Crafts reaction and then hydrogenating the cyclized product
5) Saturated copolymer of cycloolefin monomer and unsaturated double bond-containing compound
6) Addition copolymer of cycloolefin monomer and vinyl-based cyclic hydrocarbon monomer and hydrogenated product thereof
7) Altering copolymer of cycloolefin monomer and meth (acrylate)

All of the polymers of 1) to 7) above can be obtained by known methods, for example, the methods described in Japanese Unexamined Patent Publication No. 2008-107534 and Japanese Unexamined Patent Publication No. 2005-227606. For example, as the catalysts and solvents used in the ring-opening copolymerization of the above-described 2), for example, those described in paragraphs 0019 to 0024 of Japanese Unexamined Patent Publication No. 2008-107534 can be used. As the catalysts to be used in the hydrogenations 3) and 6) described above, for example, those described in paragraphs 0025 to 0028 of Japanese Unexamined Patent Publication No. 2008-107534 can be used. As the acidic compound used in the Friedel-Crafts reaction of the above-described 4), for example, those described in paragraph 0029 of Japanese Unexamined Patent Publication No. 2008-107534 can be used. As the catalysts to be used in the addition polymerizations of the above-described 5) to 7), for example, those described in paragraphs 0058 to 0063 of Japanese Unexamined Patent Publication No. 2005-227606 can be used. The alternating copolymerization reaction of the above-mentioned 7) can be performed, for example, by the method described in paragraphs 0071 to 0072 of Japanese Unexamined Patent Publication No. 2005-227606.

Among these, polymers of the above-mentioned 1) to 3) or 5) are preferable, and polymers of the above-mentioned 3) or 5) are more preferable. That is, from the viewpoints that the glass transition temperature of the obtained resin can be made high and that the light transmittance can be made high, the cycloolefin resin preferably includes at least one of a structural unit represented by the following General Formula (B-1) and a structural unit represented by the following General Formula (B-2). In addition, it is more preferable that only the structural unit represented by General Formula (B-2) is included or that both the structural unit represented by General Formula (B-1) and the structural unit represented by General Formula (B-2) are included. The structural unit represented by General Formula (B-1) is a structural unit derived from the cycloolefin monomer represented by the aforementioned General Formula (A-1), and the structural unit represented by General Formula (B-2) is a structural unit derived from the cycloolefin monomer represented by the aforementioned General Formula (A-2).

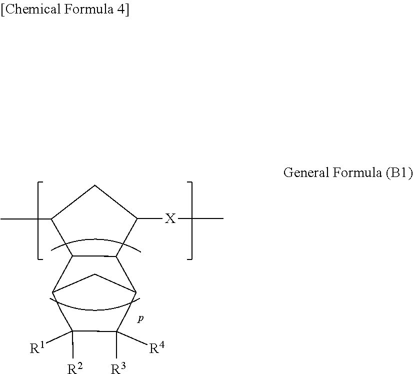

In the above General Formula (B-1), X represents —CH═CH— or —CH₂CH₂—. R¹ to R⁴ and p have the same meanings as R¹ to R⁴ and p in the above General Formula (A-1), respectively.

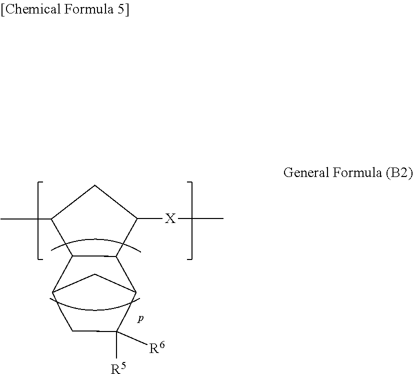

In the above General Formula (B-2), X represents —CH═CH— or —CH₂CH₂—. R⁵ to R⁶ and p respectively have the same definitions as R⁵ to R⁶ and p in General Formula (A-2).

The cycloolefin resin used in the present invention may be a commercially available product. Examples of commercially available products of cycloolefin resins include ARTON (registered trademark, the same applies hereinafter) manufactured by JSR Corporation, G (e.g., G7810 and the like), ARTON F, ARTON R (e.g., R4500, R4900, R5000, and the like), and ARTON RX (e.g., RX4500 and the like).

The intrinsic viscosity [η] inh at 30 °C of the cycloolefin polymer is preferably in a range of 0.2 to 5 cm³/g, more preferably in a range of 0.3 to 3 cm³/g, and still more preferably in a range of 0.4 to 1.5 cm³/g.

The number average molecular weight (Mn) of the cycloolefin resin is preferably in a range of 8,000 to 100,000, more preferably in a range of 10,000 to 80,000, and still more preferably in a range of 12,000 to 50,000. The weight average molecular weight (Mw) of the cycloolefin resin is preferably in a range of 20,000 to 300,000, more preferably in a range of 30,000 to 250,000, and still more preferably in a range of 40,000 to 200,000.

When the intrinsic viscosity [η] inh, the number average molecular weight, and the weight average molecular weight (Mw) are within the above ranges, the heat resistance, water resistance, chemical resistance, and mechanical properties of the cycloolefin resin, and the moldability as a substrate film are improved.

The cycloolefin resin usually has a glass transition temperature (Tg) of 110 °C or higher, preferably in a range of 110 to 350 °C, more preferably in a range of 120 to 250 °C, and still more preferably in a range of 120 to 220 °C. When Tg is 110 °C or higher, deformation under high-temperature conditions can be suppressed. On the other hand, when Tg is 350 °C or lower, molding becomes easy, and deterioration of the resin due to heat during molding can be suppressed.

In the case of an optical film containing a cycloolefin resin, the content of the cycloolefin resin is preferably 70% by mass or more, more preferably 80% by mass or more, with respect to the total mass of the optical film.

### <Fine Particles>

When the optical film contains a cycloolefin resin, it is preferable that the optical film further contains fine particles.

Examples of the fine particles of inorganic compounds include silicon dioxide; titanium dioxide; aluminum oxide; zirconium oxide; calcium carbonate; calcium carbonate; talc; clay; calcined kaolin; calcined calcium silicate; hydrated calcium silicate; aluminum silicate; magnesium silicate; and calcium phosphate.

Further, examples of the fine particles of organic compounds include: pulverized fractions of organic polymer compounds such as polytetrafluoroethylene, cellulose acetate, polystyrene, polymethyl methacrylate, polypropylmethacrylate, polymethyl acrylate, polyethylene carbonate, acrylic styrene resin, silicone-based resin, polycarbonate resin, benzoguanamine resin, melamine-based resin, polyolefin-based powder, polyester resin, polyamide-based resin, polyimide-based resin, or a polyfluoroethylene resin, and starch; and polymer compounds synthesized by suspension polymerization.

The fine particles preferably contain silicon, and more preferably contain silicon dioxide, from the viewpoint of reducing turbidity. Commercially available products of such fine particles include, for example, those available from Nippon Aerosil Co., Ltd., Aerosil (registered trademark, the same applies hereinafter) R972; R972V; R974; R812; 200; 200V; 300; R202; OX50; TT600, and the like.

### (3. 1. 3) Coloring Agent

When the optical film according to the present invention contains a coloring agent, the average light transmittance in the visible light region can be adjusted. The coloring agents may be used alone or in combination of two or more.

The content of the coloring agent is preferably in a range of 0.05 to 2.0% by mass with respect to the total mass of the resin for an optical film from the viewpoint of the balance between the luminance and the color gamut.

When two or more coloring agents are used in combination, at least one of the coloring agents is preferably a coloring agent having a maximum absorption wavelength in a wavelength region from 570 to 610 nm. Thus, the average light transmission of the optical film in the wave range of 570 to 610 nm can be reduced, and the color gamut of the display device can be prevented from being narrowed.

Furthermore, it is more preferable that the maximum absorption wavelength existing in the wavelength region of 570 to 610 nm is the highest maximum absorption wavelength of the coloring agent. The “highest maximum absorption wavelength” refers to the maximum absorption wavelength when there is only one absorption maximum wavelength, or the maximum absorption wavelength showing the maximum absorbance among a plurality of maximum absorption wavelengths when there are a plurality of maximum absorption wavelengths.

In light of balance between brightness and color gamut, the content of the coloring agent having a maximum absorption wavelength in a wavelength region of 570 to 610 nm is preferably in a range of 0.02 to 0.6% by mass relative to the total weight of the resin for an optical film. The content is more preferably in a range of 0.05 to 0.3% by mass.

Furthermore, when two or more kinds of the coloring agents are used in combination, at least one kind of the coloring agents is preferably a coloring agent having a maximum absorption wavelength in a wavelength region of 420 to 460 nm. Thus, the average light transmittance of the optical film in the visible light region can be efficiently lowered.

Furthermore, it is more preferable that the maximum absorption wavelength existing in the wavelength region of 420 to 460 nm is the maximum absorption wavelength in the coloring agent.

In light of balance between brightness and color gamut, the content of the coloring agent having a maximum absorption wavelength in a wavelength region of 420 to 460 nm is preferably in a range of 0.005 to 0.3% by weight relative to the total weight of the resins for an optical film. The content is more preferably within a range of 0.01 to 0.3% by mass.

The maximum absorption wavelength can be determined by dispersing the coloring agent in dichloromethane and measuring the absorption spectrum using an ultraviolet-visible spectrophotometer (for example, “UV-2450” (manufactured by Shimadzu Corporation)).

The coloring agent is not particularly limited, and examples thereof include dyes and pigments.

The pigment is not particularly limited, and examples thereof include organic pigments, inorganic pigments, and minerals having the following numbers listed in the Color Index.

The black pigment is not particularly limited, and examples thereof include carbon black, a magnetic material, and iron-titanium composite oxide black. The carbon black is not particularly limited, and examples thereof include channel black, furnace black, acetylene black, thermal black, and lamp black. In addition, the magnetic material is not particularly limited, and examples thereof include ferrite and magnetic.

The red or magenta pigments are not particularly limited, and examples thereof include C. I. Pigment Red 3, 5, 19, 22, 31, 38, 43, 48:1, 48:2, 48:3, 48:4, 48:5, 49:1, 53:1, 57:1, 57:2, 58:4, 63:1, 81, 81:1, 81:2, 81:3, 81:4, 88, 104, 108, 112, 122, 123, 144, 146, 149, 166, 168, 169, 170, 177, 178, 179, 184, 185, 208, 216, 226, 257, Pigment Violet 3, 19, 23, 29, 30, 37, 50, 88, Pigment Orange 13, 16, 20, 36, ruby (chromium-containing corundum), garnet, spinel, and the like.

The blue or cyan pigments are not particularly limited, and examples thereof include C. I. Pigment Blue 1, 15, 15:1, 15:2, 15:3, 15:4, 15:6, 16, 17-1, 22, 27, 28, 29, 36, 60, blue sapphire (iron and titanium-containing corundum).

The green pigments are not particularly limited, and examples thereof include C. I. Pigment Green 7, 26, 36, and 50.

The yellow pigments are not particularly limited, and examples thereof include C. I. Pigment Yellow 1, 3, 12, 13, 14, 17, 34, 35, 37, 55, 74, 81, 83, 93, 94, 95, 97, 108, 109, 110, 137, 138, 139, 153, 154, 155, 157, 166, 167, 168, 180, 185, 193, yellow sapphire (nickel-containing corundum).

Furthermore, the dyes are not particularly limited, and examples thereof include conventionally known dyes, for example, those described in paragraphs “0057” to “0060” of International Publication No. 2015/111351.

When the coloring agent is a pigment, the average secondary particle size of the pigment is not particularly limited, but is preferably 0.1 μm or more, more preferably 0.2 μm or more. When the content is within the above range, the slidability of the pigment particles is improved and the pigment particles are less likely to aggregate, and therefore, the unevenness of the transmittance of light in the visible light region of the optical film is further reduced.

The average secondary particle size of the pigment is not particularly limited, but is preferably 3 μm or less, and more preferably 2.6 μm or less. When the content is within the above range, dispersion unevenness in the optical film is less likely to occur, the unevenness of the transmittance of light in the visible light region of the optical film further decreases, and the haze value also decreases.

The average secondary particle diameter of the pigment can be determined by a method of directly measuring the size of secondary particles from an electron micrograph of the optical film. Specifically, a particle image is measured using a transmission electron micrograph (TEM) “H-7650” (manufactured by Hitachi High-Tech Corporation), the average value of equivalent circle diameters of 100 secondary particles selected at random is obtained, and this value is defined as the average secondary particle diameter.

As the coloring agent, a commercially available product or a synthesized product may be used.

Commercially available products are not particularly limited, and examples thereof include “#950” (manufactured by Mitsubishi Chemical Corporation), and “FDR series”, “FDG series”, and “FDB series” (all manufactured by Yamada Chemical Co., Ltd). Other examples include “Kayaset Black A-N” (manufactured by Nippon Kayaku Co., Ltd.), “NUBIAN® BLACK PC-5857” (manufactured by Orient Chemical Industries Co., Ltd.), and “Plast Black 8950-N” (manufactured by Arimoto Chemical Co., Ltd.).

### (3. 2) Method of Producing Optical Film

The method of manufacturing the optical film is not particularly limited, but is preferably a method in which a dope containing the resin, the rubber particles, the solvent, and any other components is prepared, then the dope is applied to the substrate, and then the substrate is dried.

Next, a method of manufacturing the optical film when using a dope will be described.

### (3. 2. 1) Preparation of Dope

### (3. 2. 1. 1) Solvent

The solvent used for the dope is not particularly limited as long as the resin and the rubber particles can be favorably dispersed therein. Examples of the solvent include alcohols such as methanol, ethanol, propanol, n-butanol, 2-butanol, tert-butanol, and cyclohexanol; ketones such as methyl ethyl ketone (MEK), methyl isobutyl ketone, and acetone; esters such as ethyl acetate, methyl acetate, ethyl lactate, isopropyl acetate, amyl acetate, and ethyl butyrate; ethers such as tetrahydrofuran (THF) and 1,4-dioxane; glycol ethers; and hydrocarbons such as toluene, benzene, cyclohexane, and n-hexane.

Examples of the glycol ethers include propylene glycol mono (C1 to C4)alkyl ether and propylene glycol mono (C1 to C4)alkyl ether ester.

Examples of propylene glycol mono (C1 to C4)alkyl ether include propylene glycol monomethyl ether (PGME), propylene glycol monoethyl ether, propylene glycol mono-n-propyl ether, propylene glycol monoisopropyl ether, and propylene glycol monobutyl ether.

Examples of propylene glycol mono (C1 to C4)alkyl ether ester include propylene glycol monomethyl ether acetate and propylene glycol monoethyl ether acetate.

These may be used alone or in combination of two or more kinds thereof.

Among these, from the viewpoint of easily dissolving the resin material, having a low boiling point, and easily increasing the drying rate and productivity, methyl ethyl ketone, ethyl acetate, acetone, or tetrahydrofuran is preferable. A solvent such as dichloromethane may be further mixed and used with the above-described solvents.

The solid content concentration of the dope is, for example, preferably in a range of 5 to 20% by mass from the viewpoints of easy adjustment of the viscosity and the like.

### (3. 2. 1. 2) Other Components

The dope may further contain other components than the above-described components, if necessary. Examples of the other components include a matting agent (fine particles), an ultraviolet absorber, and a surfactant. The addition of the matting agent can give slidability to the film. Examples of the matting agent include inorganic fine particles such as silica particles and organic fine particles having a glass transition temperature of 80 °C or higher.

Examples of the ultraviolet absorber include benzotriazole-based ultraviolet absorbers, benzophenone-based ultraviolet absorbers, and triazine-based ultraviolet absorbers.

Examples of the surfactant include anionic surfactants such as a carboxylic acid type, a sulfonic acid type, a sulfate ester type, and a phosphate ester type. Examples of the surfactant include cationic surfactants such as an alkylamine salt type and a quaternary ammonium salt type. Examples of the surfactant include amphoteric surfactants such as a carboxybetaine type, a 2-alkylimidazoline derivative type, a glycine type, and an amine oxide type. Either type can be used.

### (3. 2. 1. 3) Preparation of Dope

The above resin, rubber particles, solvent, and any other components are mixed, if necessary, with stirring under nitrogen to prepare a dope.

The order of mixing the components contained in the dope is not particularly limited. A method of mixing the components is also not particularly limited, and for example, the components may be stirred using a stirrer or the like.

The mixing time (stirring time) is not particularly limited, but is preferably within a range of 1 to 10 hours. The mixing temperature (stirring temperature) is also not particularly limited, but is preferably in a range of 20 to 50 °C.

The viscosity of the dope at 25 °C is not particularly limited as long as an optical film having a desired film thickness can be produced, but is preferably in the range of 5 to 5,000 mPa·s. When the viscosity of the dope is 5 mPa·s or more, it is easy to produce an optical film having a desired film thickness. In addition, when the viscosity is less than or equal to 5,000 mPa·s, it is possible to prevent uneven thicknesses from occurring due to an increase in the viscosity of the solution. From the same viewpoint, the viscosity of the dope is more preferably in a range of 100 to 1,000 mPa·s. The viscosity of the dope at 25 °C can be measured with an E-type viscometer.

The obtained dope may be filtered, if necessary. The filtration method is not particularly limited, and a conventionally known method can be appropriately used.

### (3. 2. 2) Preparation of Film

The optical film according to the present invention is not particularly limited, but can be produced by applying the obtained dope to the surface of a substrate, and then drying to remove the solvent from the dope. At this time, a laminated film including the substrate and the optical film is produced.

The step of applying to a substrate and the step of forming an optical film (drying step) will be described below.

### (3. 2. 2. 1) Step of Applying Dope

In this step, the dope obtained above is applied to the surface of the base material. Specifically, the dope is applied to the surface of the base material.

The base material is not particularly limited as long as it can support the optical film, but is usually preferably a resin film.

Examples of the resin film include polyester resin films (e.g, polyethylene terephthalate (PET), polytrimethylene terephthalate (PTT), polybutylene terephthalate (PBT), polyethylene naphthalate (PEN), polybutylene naphthalate (PBN), and the like), cycloolefin resin film (COP), acrylic film, cellulose-based resin films (e.g, cellulose triacetate film (TAC) and the like).

Among these, from the viewpoint of versatility and high tensile elastic modulus, a PET film, a cellulose triacetate film (TAC), or a cycloolefin resin film is preferable.

The resin film may be thermally relaxed, or may be subjected to a stretching treatment.

When the resin film is subjected to the thermal relaxation treatment, both of the crystallinity and the orientation can be reduced, and the tensile elastic modulus of the resin film can be reduced. The thermal relaxation temperature is not particularly limited, but it is preferably performed within a range of (Tg+60) to (Tg+180) °C, where Tg is the glass transition temperature of the resin constituting the resin film. The thermal relaxation may be performed before the release layer is produced, or may be performed after the release layer is produced.

In the stretching treatment, the orientation of resin molecules can be enhanced by stretching the resin film, and the tensile elastic modulus of the resin film can be enhanced. The stretching treatment may be performed, for example, in a uniaxial direction or a biaxial direction of the resin film. The stretching treatment can be performed under any conditions, and is preferably performed, for example, at a stretching ratio in a range of 120 to 900%. The stretching ratio here is a value obtained by multiplying the stretching ratio in each direction.

Whether or not the resin film is stretched (whether or not it is a stretched film) can be confirmed by, for example, whether or not there is an in-plane slow axis (an axis extending in a direction in which the refractive index is maximized).

The substrate preferably further has a release layer on the surface of the resin film. When the release layer is provided, the optical film can be easily peeled from the base material.

The release layer is not particularly limited as long as it contains a known release agent or mold release agent. The release agent contained in the release layer may be a silicone-based release agent or a non-silicone-based release agent.

Examples of the silicone-based release agent include known silicone-based resins.

Examples of the non-silicone-based release agent include long-chain alkyl pendant type polymer obtained by reacting polyvinyl alcohol or ethylene-vinyl alcohol copolymer with long-chain alkyl isocyanate, olefin-based resin (e.g, copolymerized polyethylene, cyclic polyolefin, polymethylpentene and the like), polyarylate resin (e.g, polycondensates of aromatic dicarboxylic acid components and dihydric phenol components, and the like), fluororesin (e.g, Polytetrafluoroethylene (PTFE), Polyvinylidene fluoride (PVDF), Polyvinyl fluoride (PVF), copolymer of tetrafluoroethylene and perfluoroalkoxyethylene (PFA), copolymer of tetrafluoroethylene and hexafluoropropylene (FEP), copolymers of tetrafluoroethylene and ethylene (ETFE) and the like).

The release layer may further contain an additive as necessary. Examples of the additive include filler, lubricant (wax, fatty acid ester, fatty acid amide, and the like), stabilizer (antioxidant, heat stabilizer, light stabilizer, and the like), flame retardant, viscosity modifier, thickener, defoamer, and ultraviolet absorber.

The thickness of the release layer is not particularly limited as long as desired releasability can be obtained, but is preferably in a range of 0.1 to 1.0 μm.

The thickness of the base material is not particularly limited, but is preferably in a range of 10 to 100 μm and more preferably in a range of 25 to 50 μm.

The method of applying the dope is not particularly limited, and examples thereof include known methods such as a back coating method, a gravure coating method, a spin coating method, a wire bar coating method, and a roll coating method.

Among these, a back coating method is preferable from the viewpoint of forming a thin coating film having a uniform thickness.

### (3. 2. 2. 2) Step of Forming Optical Film

Then, the solvent is removed from the dope applied to the base material to form an optical film.

Specifically, the dope applied to the base material is dried. Examples of the drying method include blowing or heating. Among these, from the viewpoint of easily suppressing the curling of the laminated film, it is preferable to dry the laminated film by blowing air.

By adjusting the drying conditions (for example, the drying temperature, the solvent concentration in the atmosphere, the drying time, and the like), the amount of the residual solvent in the coating film after drying, that is, the optical film can be set to a certain level or less. Furthermore, the distribution state of the rubber particles in the optical film can be adjusted by the drying conditions. Specifically, from the viewpoint of facilitating uneven distribution of the rubber particles, it is preferable that a solvent having good affinity with the rubber particles is used, the drying temperature is high, and the solvent concentration in the atmosphere is low.

When the boiling point of the solvent is defined as Tb (°C), the drying temperature is preferably in a range of (Tb−50) to (Tb+50) °C, and more preferably in a range of (Tb−40) to (Tb+40) °C. When the drying temperature is equal to or higher than the lower limit value, the evaporation rate of the solvent can be increased, and the rubber particles are easily unevenly distributed. In addition, when the concentration is equal to or less than the upper limit value, it is possible to prevent the concentration of the solvent in the atmosphere from becoming excessively high. For example, when a mixed solvent of acetone and methanol is used, the drying temperature is preferably 40 °C or higher.

The concentration of the solvent in the atmosphere during drying is preferably in a range of 0.10 to 0.30% by mass, and more preferably 0.10 to 0.20% by mass. When the content is 0.10% by mass or more, excessive evaporation of the solvent can be suppressed, and cracking of the coating film can be made less likely. In addition, when the amount is 0.30% by mass or less, the evaporation rate of the solvent from the coating film can be appropriately increased, and the rubber particles are easily unevenly distributed on the surface. The solvent concentration in the atmosphere can be adjusted by the drying temperature and the dew-point temperature in the drying furnace. Furthermore, the concentration of the solvent in the atmosphere can be measured with an infrared gas concentration meter.

The optical film according to the present invention is obtained by peeling off the base material from the laminated film of the base material and the optical film thus obtained.

### (3. 3) Physical Properties of Optical Film

The storage elastic modulus of the optical film at 25 °C is preferably in a range of 0.1 to 3.5 GPa and more preferably in a range of 1.0 to 3.5 GPa from the viewpoints of impact resistance and flexibility.

The loss tangent (tan δ₂) of the optical film at 25 °C is not particularly limited as long as it satisfies the relationship of the above Formula (1), but it is preferably in a range of 0.01 to 0.3, more preferably in a range of 0.05 to 0.3.

The storage elastic modulus and loss tangent (tan δ₂) of the optical film at 25 °C can be adjusted by appropriately selecting the kind, content, and the like of materials (resin, rubber particles, and the like).

The storage elastic modulus and the loss tangent at 25 °C of the optical film can be measured with a rheometer apparatus “RSA-3” (manufactured by TA Instruments Japan Inc.) under the following test conditions.

### Test Conditions (Dynamic Viscoelasticity Test)

Tester: Dynamic viscoelasticity measuring apparatus “RSA-3” (manufactured by TA Instruments Japan Inc.)
Deformation method: Tension
Preload weight: 55 g
Temperature range: −70 to 200 °C.
Frequencies: 1.0 Hz
Displacement: #0.1%
Samples: 5 mm wide
Distance between chucks: 20 mm

The optical film preferably has an in-plane retardation (Rₒ) represented by the following Expression in a range of −10 to 10 nm.

R₀═(Nx−Ny)×d Expression:

In the above expression, Nx is the in-plane maximum refractive index of the optical film, Ny is the in-plane minimum refractive index of the optical film, and d is the thickness of the optical film.

The in-plane retardation (Rₒ) can be measured using an automatic birefringence meter. For example, it can be measured with the automatic birefringence meter “KOBRA (R)-21ADH” (manufactured by Oji Scientific Instruments Co., Ltd.) under an environment of a temperature of 23 °C and a relative humidity of 55% at a wave length 590 nm.

The thickness of the optical film is preferably in a range of 10 to 60 μm, more preferably in a range of 15 to 50 μm, and still more preferably in a range of 20 to 40 μm, from the viewpoint of thinning of the laminate of the present invention.

The glass transition temperature of the optical film is preferably within a range of −30 to 180 °C from the viewpoint of impact resistance. When a plurality of glass transition temperatures are observed in measuring the glass transition temperature of the optical film, the lowest glass transition temperature observed is defined as the glass transition temperature of the optical film. The glass transition temperature can be measured by the above-described method.

3. Method for Producing Laminate The method of manufacturing the laminate of the present invention is not particularly limited, and examples thereof include a method in which the glass layer (thin film glass), the elastic layer (ultraviolet curable acrylic adhesive), and the optical film are sequentially arranged.

### 4. Physical Properties of Laminate

In the laminate of the present invention, when the loss tangents of the elastic layer and the optical film at 25 °C are defined as tan δ₁ and tan δ₂, respectively, the value of the ratio of the loss tangents (tan δ₁/tan δ₂) satisfies the following Formula (1).

1.0≤tan δ₁/tan δ₂≤3.0. Formula (1):

The loss tangents of the elastic layer and the optical film at 25 °C can be measured by the above-described method.

As described above, the elastic layer according to the present invention is preferably made of an adhesive and has relatively high stress relaxation properties. With respect to such an elastic layer, the optical film according to the present invention satisfies the above Formula (1). That is, it is considered that the effect of the present invention can be obtained by using an optical film having a stress relaxation property to some extent.

The thickness of the laminate of the present invention is preferably in a range of 30 to 110 μm, and more preferably in a range of 55 to 95 μm, from the viewpoint of achieving both impact resistance and flexibility.

### 5. Display Device

The display device of the present invention includes the above-described laminate. That is, the display device including a light-emitting device and the above-described laminate can be provided.

Furthermore, the glass layer is preferably arranged at a position more outward of the display device than the optical film. That is, the glass layer in the laminate is preferably disposed closest to the viewing side.

The light-emitting device is not particularly limited, and examples thereof include a plasma display device and an electroluminescent light-emitting device.

### Example

Hereinafter, the present invention will be specifically described with reference to Examples, but the present invention is not limited thereto. In the examples, “part(s)” or “%” means “part(s) by mass” or “mass %” unless otherwise specified.

In the following examples, operations were performed at room temperature (25 °C) unless otherwise specified.

### 1. Measurement Method

The glass transition temperature, the weight average molecular weight, the storage elastic modulus, and the loss tangent were measured by the following methods.

### (Glass Transition Temperature)

The glass transition temperature (Tg) of each layer was measured in accordance with JIS K 7121 (2012) using a differential scanning colorimetry (DSC).

### (Weight Average Molecular Weight)

The weight-average molecular weight (Mw) of the resin in each layer was measured with gel permeation chromatography “HLC8220GPC” (manufactured by Tosoh Corporation) and columns “TSK-GEL G6000”, “HXL-G5000”, “HXL-G5000”, “HXL-G4000”, and “HXL-G3000HXL” (all manufactured by Tosoh Corporation, in tandem).

The sample 20 mg±0. 5 mg was dissolved in 10 mL of tetrahydrofuran and filtered through a 0.45 mm filter. Then, this liquid was injected into a column (at a temperature of 40 °C) by 100 mL injection, and measurement was performed with an RI detector at a temperature of 40 °C, and a value in terms of styrene was obtained.

### (Storage Elastic Modulus and Loss Tangent of Elastic Layer)

The storage elastic modulus and the loss tangent of the elastic layer at 25 °C were measured with a viscoelasticity measuring apparatus “ARES-G2” (manufactured by TA Instruments Japan Inc.) under the following test conditions.
Test Conditions (dynamic viscoelasticity test)
Tester: Viscoelasticity measuring apparatus “ARES G2” (manufactured by TA Instruments Japan Inc.)
Deformation method: Rotation
Temperature range: −50 to 100 °C.
Frequencies: 1 Hz
Displacement: Strain 0.05%
Sample size (e.g., form): φ8 mm, thickness about 1 mm
Distance between chucks: Automatically variable so that the load is 10 g (approximately equal to the sample thickness).

### (Storage Elastic Modulus and Loss Tangent of Optical Film)

The storage elastic modulus and the loss tangent at 25 °C of the optical film were measured with a rheometer apparatus “RSA-3” (manufactured by TA Instruments Japan Inc.) under the following test conditions.

### Test Conditions (Dynamic Viscoelasticity Test)

Tester: Dynamic viscoelasticity measuring apparatus “RSA-3” (manufactured by TA Instruments Japan Inc.)
Deformation method: Tension
Preload weight: 55 g
Temperature range: −70 to 200 °C.
Frequencies: 1.0 Hz
Displacement: +0.1%
Samples: 5 mm wide
Distance between chucks: 20 mm

### 2. Preparation of Laminate

### (1. 2) Preparation of Glass Layer (Thin Film Glass)

### (1. 1) Preparation of Glass Layer 1

Thin film glass 1 (soda-lime glass) having a dimension of 12 inches was prepared according to the following steps.
(Step 1) Thin film glass was formed on a carrier substrate having a bonding surface so that the first surface of the thin film glass is in contact with the carrier substrate. Then, the contact film having an adhesive force (hereinafter, also referred to as a “contact film”) was bonded to the second surface opposite to the first surface of the thin film glass.
(Step 2) Next, the thin film glass was peeled off from the carrier substrate by the contact film having a high adhesive force.
(Step 3) The contact film was removed from the second surface of the thin film glass peeled off from the carrier substrate by the weakening processing (electromagnetic irradiation) for weakening the adhesion of the contact film.

In Step 1, the thin film glass was produced so as to be in contact with the carrier substrate having a thickness of 500 μm and to have a predetermined thickness, and then the following contact film was bonded. Next, in Step 2, the thin film glass was peeled off from the carrier substrate together with the contact film for 30 seconds.

A commercially available product “NDS4150-20” was used as the contact film. “NDS4150-20” is a 150 μm-thick film including polyolefin (PO), and further includes a 10 μm-thick adhesive layer.

Next, in Step 3, the exposed contact film was subjected to the weakening processing to reduce the adhesive force. In the weakening processing, the contact film was irradiated with ultraviolet rays having 365 nm wavelength for 10 seconds. The illuminance of the ultraviolet rays was 500 mW/cm² and the integrated light amount was 500 mJ/cm². The adhesive strength before the weakening processing was 11 N/25 mm, but the adhesive strength after the weakening processing was reduced to 0. 4 N/25 mm. Thus, the contact film could be easily peeled off from the thin film glass, and Thin film glass 1 having a thickness of 30 μm was obtained.

### (1. 2) Preparation of Glass Layers 2 to 4

Glass layers 2 to 4 were produced in the same manner as in the production of the glass layer 1, except that the thickness was changed to 10 μm, 5 μm, and 40 μm, respectively.

### (2) Preparation of Elastic Layer

### (2. 1) Preparation of Elastic Layer 1

(2. 1. 1) Preparation of Ultraviolet Curable Acrylic Adhesive Composition (a-1)

A monomer mixture composed of the following components was prepared.

| | | |
|---|---|---|
| 2-ethylhexyl acrylate (2EHA) | 78 | parts by mass |
| N-vinyl-2-pyrrolidone (NVP) | 18 | parts by mass |
| 2-hydroexyethyl acrylate (HEA) | 4 | parts by mass |

The following components were added as a photopolymerization initiator.

| | |
|---|---|
| 1-hydroxycyclohexyl phenyl ketone | 0.035 parts by mass |
| 2,2-dimethoxy-1,2-diphenylethan-1-one | 0.035 parts by mass |

The following commercially available products were used as the photopolymerization initiators.

1-hydroxycyclohexyl phenyl ketone: “Omnirad® 184” (having an absorption band at wavelength of 200 to 370 nm, manufactured by IGM Resins B. V.).

2,2-dimethoxy-1,2-diphenylethane-1-one: “Omnirad® 651” (having an absorption band at wavelength of 200 to 380 nm, manufactured by IGM Resins B. V.).

Thereafter, the mixture was irradiated with ultraviolet rays until the viscosity (measurement conditions: BH viscometer, No. 5 rotor, 10 rpm, measurement temperature of 30 °C) became about 20 Pa·s. Next, a prepolymer composition (P) (polymerization rate: 8%) in which some of the monomer components were polymerized was obtained.

Next, the following components were added to and mixed with the prepolymer composition to obtain an acrylic adhesive composition.

| | | |
|---|---|---|
| Hexanediol diacrylate (HDDA) | 0.15 | parts by mass |
| Silane coupling agent “KBM-403” (manufactured | 0.3 | parts by mass |
| by Shin-Etsu Chemical Co., Ltd.) | | |

The following components were added to the obtained acrylic adhesive composition, and the mixture was stirred to obtain an ultraviolet curable acrylic adhesive composition (a-1).

| | | |
|---|---|---|
| 2,4-bis-[{4-(4-ethylhexyloxy)-4-hydroxy}-phenyl]- | 1.4 | Parts by mass |
| 6-(4-methoxyphenyl)-1,3,5-triazin | | |
| (added after dissolving in n-butyl acrylate so that the | | |
| solid content concentration becomes 15% by mass) | | |
| Bis(2,4,6-trimethylbenzoyl)-phenylphosphineoxide | 0.2 | parts by mass |

The following commercially available products were used.

2,4-bis-[{4-(4-ethylhexyloxy)-4-hydroxy}-phenyl]-6-(4-methoxyphenyl)-1,3,5-triazin: “Tinosorb® S” (manufactured by BASF Japan Ltd.).

Bis(2,4,6-trimethylbenzoyl)-phenylphosphine oxide: “Omnirad® 819” (having an absorption band in a wavelength range of 200 to 450 nm, manufactured by IGM Resins B.V.)

### (2. 1. 2) Formation of Elastic Layer 1

The resultant ultraviolet curable acryl-based adhesive composition (a-1) was applied onto the surface of the optical film 1 described later so as to have a thickness of 5 μm after curing, and a release film was further bonded onto the surface thereof. Thereafter, the composition was cured by irradiation with ultraviolet rays under conditions of an illuminance of 6.5 mW/cm² and an integrated light amount of 1500 mJ/cm², and the release film was peeled off, thereby forming the elastic layer 1 on the optical film 1.

Tg of the elastic layer 1 was −20 °C. Further, the storage elastic modulus at 25 °C was 8.00, and the loss tangent (tan δ₁) was 0.20.

The sample of the elastic layer was prepared by forming an elastic layer on a surface of a release film instead of the optical film 1 by the same method, and then peeling off the release film. Then, the glass transition temperature, the storage elastic modulus, and the loss tangent were measured.

### (2. 2) Preparation of Elastic Layer 2

(2. 2. 1) Preparation of Ultraviolet Curable Acrylic Adhesive Composition (a-2)

The following ingredients were mixed.

| | | |
|---|---|---|
| Isostearic acid acrylate | 35 | parts by mass |
| Hydroxybutyl acrylate | 30 | parts by mass |
| Isobornyl acrylate | 30 | parts by mass |
| The prepolymer composition (P) described above | 4 | parts by mass |

Then, the following photopolymerization initiator was added, and the mixture was stirred to obtain an ultraviolet curable acrylic adhesive composition (a-2).

| | |
|---|---|
| Photopolymerization initiator “Omnirad (R) 819” | 1 part by weight |

### (2. 2. 2) Formation of Elastic Layer 2

Using an inkjet head “KM1024iLHE-30” (manufactured by Konica Minolta, Inc.) in an inkjet image forming apparatus (manufactured by Tritek, Inc.), the ink (the obtained ultraviolet curable acrylic adhesive composition (a-2)) was applied onto the surface of the optical film 1 so as to be 5 μm thick after being cured. The applied ink was irradiated with the ultraviolet rays having a wavelength of 395 nm at an intensity of 200 mW/cm² by using an ultraviolet irradiation device (manufactured by Phoseon Technology). The integrated light amount was defined as 1000 mJ/cm². A transparent release film was attached to the surface of the ink temporarily cured by the irradiation, and was further irradiated with ultraviolet rays having a wavelength of 395 nm at an intensity of 200 mW/cm² and an integrated light quantity of 1000 mJ/cm². The ink was fully cured, and the release film was peeled off, thereby producing the elastic layer 2 on the optical film 1.

The storage elastic modulus at 25 °C was 1.20, and the loss tangent (tan δ₁) was 0.30.

### (2. 3) Preparation of Elastic Layer 3

Elastic Layer 3 was produced in the same manner as in the preparation of Elastic Layer 1 except that the ultraviolet irradiation conditions were changed.

The storage elastic modulus at 25 °C was 10.00, and the loss tangent (tan 1) was 0.15.

### (2. 4) Preparation of Elastic Layer 4

Elastic Layer 4 was produced in the same manner as in the preparation of Elastic Layer 1 except that the ultraviolet irradiation conditions were changed.

The storage elastic modulus at 25 °C was 0.50, and the loss tangent (tan 01) was 0.30.

### (2. 5) Preparation of Elastic Layer 5

Elastic Layer 5 was produced in the same manner as in the preparation of Elastic Layer 1 except that the ultraviolet irradiation conditions were changed.

The storage elastic modulus at 25 °C was 1.20, and the loss tangent (tan δ₁) was 0.10.

### (2. 6) Preparation of Elastic Layer 6

Elastic Layer 6 was produced in the same manner as in the preparation of Elastic Layer 1 except that the thickness was changed to 2 μm.

The storage elastic modulus at 25 °C was 8.00, and the loss tangent (tan 01) was 0.20.

### (2. 7) Preparation of Elastic Layer 7

Elastic Layer 7 was produced in the same manner as in the preparation of Elastic Layer 1 except that the thickness was changed to 15 μm.

The storage elastic modulus at 25 °C was 8.00, and the loss tangent (tan δ₁) was 0.20.

### (2. 8) Preparation of Elastic Layer 8

Elastic Layer 8 was produced in the same manner as in the preparation of Elastic Layer 1 except that the thickness was changed to 1 μm.

The storage elastic modulus at 25 °C was 8.00, and the loss tangent (tan δ₁) was 0.20.

### (2. 9) Preparation of Elastic Layer 9

Elastic Layer 9 was produced in the same manner as in the preparation of Elastic Layer 1 except that the thickness was changed to 20 μm.

The storage elastic modulus at 25 °C was 8.00, and the loss tangent (tan 01) was 0.20.

### (2. 10) Preparation of Elastic Layer 101

Elastic Layer 101 was produced in the same manner as in the preparation of Elastic Layer 1 except that the thickness was changed to 25 μm.

The storage elastic modulus at 25 °C was 0.05, and the loss tangent (tan δ₁) was 0.30.

### (2. 11) Preparation of Elastic Layer 102

Elastic Layer 102 was produced in the same manner as in the preparation of Elastic Layer 1 except that the ultraviolet irradiation conditions were changed.

The storage elastic modulus at 25 °C was 8.00, and the loss tangent (tan 61) was 0.05.

### (2. 12) Preparation of Elastic Layer 103

Elastic Layer 103 was produced in the same manner as in the preparation of Elastic Layer 1 except that the ultraviolet irradiation conditions were changed.

The storage elastic modulus at 25 °C was 0.50, and the loss tangent (tan δ₁) was 0.40.

### (2. 13) Preparation of Elastic Layer 104

Elastic Layer 104 was produced in the same manner as in the preparation of Elastic Layer 1 except that the ultraviolet irradiation conditions were changed.

The storage elastic modulus at 25 °C was 0.40, and the loss tangent (tan δ₁) was 0.30.

### (2. 13) Preparation of Elastic Layer 105

Elastic Layer 105 was produced in the same manner as in the preparation of Elastic Layer 1 except that the ultraviolet irradiation conditions were changed.

The storage elastic modulus at 25 °C was 11.00, and the loss tangent (tan δ₁) was 0.14.

### (3) Preparation of Optical Film

### (3. 1) Preparation of Optical Film 1

(3. 1. 1) Thermoplastic (Meth)Acrylic Resin MMA (methyl methacrylate)/PMI (phenylmaleimide)/MA (methyl acrylate) copolymers (mass ratio of 85/10/5, Mw: 2,000,000, Tg: 122 °C) were prepared as (meth)acrylic resins.

### (3. 1. 2) Rubber Particles (Graft Copolymer)

Rubber particles (graft copolymer) prepared by the following method were used.

The following components were charged into an 8 L polymerization apparatus equipped with a stirrer to prepare Solution I.

| | | |
|---|---|---|
| Deionized water | 180 | parts by mass |
| Polyoxyethylene lauryl ether phosphoric acid | 0.002 | parts by mass |
| Boric acid | 0.4725 | parts by mass |
| Sodium carbonate | 0.04725 | parts by mass |
| Sodium hydroxide | 0.0076 | parts by mass |

After the inside of the polymerization apparatus was sufficiently replaced with nitrogen gas, the internal temperature was adjusted to 80 °C, and the following components were added.

| | |
|---|---|
| Potassium persulfate (added as 2% by | 0.021 parts by mass |
| mass aqueous solution) | |

Subsequently, a monomer mixture (c′) composed of the following components was prepared.

| | | |
|---|---|---|
| Methyl methacrylate | 84.6% | by mass |
| n-Butyl acrylate | 5.9% | by mass |
| Styrene | 7.9% | by mass |
| Allyl methacrylate | 0.5% | by mass |
| n-Octyl mercaptan | 1.1% | by mass |

Next, a mixed solution containing the following components was prepared.

| | | |
|---|---|---|
| Monomer mixture (c′) | 21 | parts by mass |
| Polyoxyethylene lauryl ether phosphoric acid | 0.07 | parts by mass |

Then, the mixed solution was continuously added to the above Solution I over 63 minutes. Further, the polymerization reaction was continued for 60 minutes to obtain a hard polymer (crosslinked polymer (c)) contained in the innermost portion.

Thereafter, the following components were added to prepare Solution II.

| | |
|---|---|
| Sodium hydroxide (added as 2% by mass | 0.021 parts by mass |
| aqueous solution) | |
| Potassium persulfate (added as 2% by | 0.062 parts by mass |
| mass aqueous solution) | |

Subsequently, a monomer mixture (a′) composed of the following components was prepared.

| | | |
|---|---|---|
| n-Butyl acrylate | 80.0% | by mass |
| Styrene | 18.5 | mass % |
| Allyl methacrylate | 1.5% | by mass |

Next, a mixed solution containing the following components was prepared.

| | | |
|---|---|---|
| Monomer mixture (a′) | 39 | parts by mass |
| Polyoxyethylene lauryl ether phosphoric acid | 0.25 | parts by mass |

Then, the mixed solution was continuously added to Solution II over 117 minutes.

Thereafter, the following components were added.

| | |
|---|---|
| Potassium persulfate (added as 2% by mass | 0.012 parts by mass |
| aqueous solution) | |

The polymerization reaction was continued for 120 minutes to obtain a soft layer (a layer formed of the acrylic rubbery polymer (a)). The glass transition temperature (Tg) of the soft layer, which was calculated by averaging the glass transition temperatures of the homopolymers of the respective monomers constituting the acrylic rubbery polymer (a) according to the composition ratio, was −30 °C.

Thereafter, the following components were added to obtain Solution III.

| | |
|---|---|
| Potassium persulfate (added as 2% by mass | 0.04 parts by mass |
| aqueous solution) | |

Then, a monomer mixture (b′) composed of the following components was prepared.

| | | |
|---|---|---|
| Methyl methacrylate | 97.5% | by mass |
| n-Butyl acrylate | 2.5% | by mass |

The following monomer mixture (b′) was continuously added to Solution III over 78 minutes. Further, the polymerization reaction was continued for 30 minutes to obtain a methacrylic polymer (b).

| | |
|---|---|
| Monomer mixture (b′) | 26.1 parts by mass |

The obtained methacrylic polymer (b) was put into a 3% by mass sodium sulfate warm aqueous solution to be salted out and coagulated. Next, after dehydration and washing were repeated, the product was dried to obtain acrylic graft copolymer particles (rubber particles) having a three layer structure.

The average particle size of the obtained rubber particles was measured with a zeta potential and particle size measurement system “ELSZ-2000ZS” (manufactured by Otsuka Electronics Co., Ltd.) and found to be 200 nm.

The rubber particles had a glass transition temperature (Tg) of −30 °C.

### (3. 1. 3) Preparation of Surfactant Solution

The following components were mixed and dissolved to prepare a surfactant solution.

| | | |
|---|---|---|
| Methyl ethyl ketone (MEK) | 98 | parts by mass |
| Phosphanol ML-220 (polyoxyethylene lauryl | 2 | parts by mass |
| ether phosphate, manufactured by Toho | | |
| Chemical Industry Co., Ltd) | | |

### (3. 1. 4) Preparation of Dope

The following components as a solvent were loaded into a dissolution tank in which the nitrogen concentration was controlled to 98.5% by volume and the oxygen concentration was controlled to 1.5% by volume.

| | |
|---|---|
| Methyl ethyl ketone | 85.3 parts by mass |

Next, the following components were added into the dissolution tank containing the solvent, and stirred for 30 minutes.

| | |
|---|---|
| Surfactant solution | 15 parts by mass |

Thereafter, the following components were added with stirring, and stirring was continued at 23 °C for 1 hour to disperse the graft copolymer.

| | |
|---|---|
| Acrylic graft copolymer particles | 2.2 parts by mass |

Next, the following components were added to the dissolution tank with stirring, and then the mixture was stirred at 23 °C for 4 hours to completely dissolve the solid content, thereby completing the dope.

| | |
|---|---|
| Thermoplastic (meth)acrylic resin | 8.8 parts by mass |

### (3. 1. 5) Formation of Optical Film 1

As a base material, a PET film “TN100” (manufactured by Toyobo Co., Ltd., 50 μm thick, with a release layer containing a non-silicone-based release agent) was prepared. The dope was applied onto the release layer of the PET film by using a die a back coating method, and then dried at 80 °C in an atmosphere having a solvent concentration of 0.18% by volume. Then, the base material was peeled off to obtain Optical Film 1 having a thickness of 20 μm. The optical film had a glass transition temperature (Tg) of 10 °C. Further, the loss tangent (tan δ₂) at 25 °C was 0.10.

### (3. 2) Preparation of Optical Film 2

Optical Film 2 was produced in the same manner as in the preparation of Optical Film 1 except that the type of the resin was changed to a cycloolefin resin (COP).

The loss tangent (tan δ₂) at 25 °C was 0.08.

### (3. 3) Preparation of Optical Films 3 to 6

Optical Films 3 to 6 were produced in the same manner as in the preparation of Optical Film 1, except that the contents of the rubber particles were changed to 10% by mass, 80% by mass, 5% by mass, and 90% by mass, respectively.

The loss tangents (tan δ₂) at 25 °C were 0.08, 0.15, 0.07, and 0.15, respectively.

### (3. 4) Preparation of Optical Films 7 to 8

Optical Films 7 and 8 were produced in the same manner as in the preparation of Optical Film 1, except that the particle diameter of the rubber particles was changed.

The loss tangents (tan δ₂) at 25 °C were 0.14 and 0.08, respectively.

### (35) Preparation of Optical Film 101

Optical Film 101 was produced in the same manner as in the preparation of Optical Film 1 except that the type of the resin was changed to polyethylene terephthalate (PET) and the rubber particles were not added.

The loss tangent (tan δ₂) at 25 °C was 0.01.

### (3.6) Preparation of Optical Film 102

Optical Film 102 was produced in the same manner as in the preparation of Optical Film 1 except that the rubber particles were not added.

The loss tangent (tan δ₂) at 25 °C was 0.07.

### (4) Preparation of Laminate

### (4. 1) Preparation of Laminate 1

Thin film glass 1 and Elastic Layer 1 (Elastic Layer 1 formed on Optical Film 1) were bonded to each other. Thus, Laminate 1 including the thin film glass (glass layer), the elastic layer, and the optical film in this order was obtained.

The value of the ratio of loss tangents (tan δ₁/tan δ₂) at 25 °C of Laminate 1 was 2.0.

### (4. 2) Preparation of Laminates 2 to 20 and 101 to 106

The thin film glass, the elastic layer, and the optical film were bonded together so as to obtain the combinations listed in Table I, and Laminates 2 to 20 and 101 to 106 were obtained.

The value of the ratio of loss tangents (tan δ₁/tan δ₂) at 25 °C of each laminate was as shown in Table I.

### 2. Evaluation

The obtained laminates were evaluated as follows.

### (1) Bending Test

Each of the obtained laminates was cut into a size of 20 mm in TD direction (lateral direction)×110 mm in MD direction (longitudinal direction). Using a no-load U-shape stretch tester “DLDMLH-FS” (manufactured by Yuasa System Co., Ltd), the bending radius was set to 1 mm, and the sample was bent 100 times at a speed of 1 time/second. At that time, the positions of both MD-side end portions 10 mm of the sample were fixed, and the portion to be bent was the 20 mm×90 mm portion. After the completion of the bending, the sample was placed on a plane with the bent inner side down, and the haze of the bent portion was measured with a haze meter “NDH4000” (manufactured by Nippon Denshoku Industries Co., Ltd). The haze value before the bending test was defined as a and the haze value after the bending test was defined as b, and the difference (b−a) between the values was obtained and evaluated according to the following criteria. Note that if the evaluation is A or higher (A to AAA), the sample is practical.
AAA: less than 0.1
AA: 0.1 or more and less than 0.3
A: 0.3 or more and less than 0.8
B: 0.8 or more and less than 1.1
C: more than 1.1

### (2) Pen Drop Test

The optical laminate obtained above was disposed on a Bakelite substrate manufactured by Sanhayato Corporation such that the optical film and the substrate were in contact with each other and the surface of the thin film glass faced upward. A ballpoint pen having a pen tip radius (R) of 0.35 mm and a weight of (m) 12 g was dropped onto the surface of the thin film glass while changing the drop height, and the height when the thin film glass was broken was evaluated according to the following criteria. When the evaluation is A or higher (A to AAA), the sample is practical.
AAA: not broken even when dropped from 5 cm high
AA: not broken when dropped from 4 cm high, but broken when dropped from 5 cm high
A: not broken when dropped from 3 cm high, but broken when dropped from 4 cm high
B: minute crack visible with microscope when dropped from 3 cm high
C: crack visible to eye when dropped from 3 cm high

### (3) Falling Ball Test

The impact resistance of the inner module was evaluated by dropping a 4.3 g stainless-steel ball onto each laminate. The drop height was measured from the bottom of the ball to the surface of the sample. The ball was dropped through a capillary to ensure that it hit the sample surface at an angle of about 90 degrees.

The height when a crack was observed in the internal module was evaluated according to the following criteria. When the evaluation is A or higher (A to AAA), the sample is practical.
AAA: A crack was observed when the ball was dropped from 10 cm high.
AA: No crack was observed when the ball was dropped from 8 cm high, but a crack was observed when the ball was dropped from 10 cm high.
A: No crack was observed when the ball was dropped from 6 cm high, but a crack was observed when the ball was dropped from 8 cm high.
B: No crack was observed when the ball was dropped from 4 cm high, but a crack was observed when the ball was dropped from 6 cm high.
C: No crack was observed when the ball was dropped from 2 cm high, but a crack was observed when the ball was dropped from 4 cm high.

The configuration of the laminates for each layer and the evaluation results of the laminates are shown in Table I and Table II.

Note that “-” means that the item is not contained.

“Tan δ₁” and “tan δ₂” represent loss tangents of the elastic layer and the optical film, respectively, and “tan δ₁/tan δ₂” represents a value of a ratio of the loss tangents.

TABLE 1

| | | | Elastic Layer | | | | | | | | | |
|---|---|---|---|---|---|---|---|---|---|---|---|---|
| | | | | | Storage | | Optical Film | | | | | |
| | Glass Layer | | | | Elastic | | | | Rubber Particles | | | |
| Laminate | | Thickness | | Thickness | Modulus | | | Resin | | Content | | tan δ₁/ |
| No. | No. | [μm] | No. | [μm] | [MPa] | tan δ₁ | No. | Type | Type | [% by mass] | tan δ₂ | tan δ₂ |
| 1 | 1 | 30 | 1 | 5 | 8.00 | 0.20 | 1 | Thermoplastic | P1 | 20 | 0.10 | 2.0 |
| | | | | | | | | (Meth)acrylic | | | | |
| 2 | 1 | 30 | 2 | 5 | 1.20 | 0.30 | 1 | Thermoplastic | P1 | 20 | 0.10 | 3.0 |
| | | | | | | | | (Meth)acrylic | | | | |
| 3 | 1 | 30 | 3 | 5 | 10.00 | 0.15 | 1 | Thermoplastic | P1 | 20 | 0.10 | 1.5 |
| | | | | | | | | (Meth)acrylic | | | | |
| 4 | 1 | 30 | 4 | 5 | 0.50 | 0.30 | 1 | Thermoplastic | P1 | 20 | 0.10 | 3.0 |
| | | | | | | | | (Meth)acrylic | | | | |
| 6 | 1 | 30 | 5 | 5 | 1.20 | 0.10 | 1 | Thermoplastic | P1 | 20 | 0.10 | 1.0 |
| | | | | | | | | (Meth)acrylic | | | | |
| 7 | 1 | 30 | 1 | 5 | 8.00 | 0.20 | 2 | COP | P1 | 20 | 0.08 | 2.5 |
| 8 | 1 | 30 | 1 | 5 | 8.00 | 0.20 | 3 | Thermoplastic | P1 | 10 | 0.08 | 2.0 |
| | | | | | | | | (Meth)acrylic | | | | |
| 9 | 1 | 30 | 1 | 5 | 8.00 | 0.20 | 4 | Thermoplastic | P1 | 80 | 0.15 | 2.0 |
| | | | | | | | | (Meth)acrylic | | | | |
| 10 | 1 | 30 | 1 | 5 | 8.00 | 0.20 | 5 | Thermoplastic | P1 | 5 | 0.07 | 2.0 |
| | | | | | | | | (Meth)acrylic | | | | |
| 11 | 1 | 30 | 1 | 5 | 8.00 | 0.20 | 6 | Thermoplastic | P1 | 90 | 0.15 | 2.0 |
| | | | | | | | | (Meth)acrylic | | | | |
| 12 | 1 | 30 | 1 | 5 | 8.00 | 0.20 | 7 | Thermoplastic | P2 | 20 | 0.14 | 1.4 |
| | | | | | | | | (Meth)acrylic | | | | |
| 13 | 1 | 30 | 1 | 5 | 8.00 | 0.20 | 8 | Thermoplastic | P3 | 20 | 0.08 | 2.5 |
| | | | | | | | | (Meth)acrylic | | | | |
| 14 | 2 | 10 | 1 | 5 | 8.00 | 0.20 | 1 | Thermoplastic | P1 | 20 | 0.10 | 2.0 |
| | | | | | | | | (Meth)acrylic | | | | |
| 15 | 3 | 5 | 1 | 5 | 8.00 | 0.20 | 1 | Thermoplastic | P1 | 20 | 0.10 | 2.0 |
| | | | | | | | | (Meth)acrylic | | | | |
| 16 | 4 | 40 | 1 | 5 | 8.00 | 0.20 | 1 | Thermoplastic | P1 | 20 | 0.10 | 2.0 |
| | | | | | | | | (Meth)acrylic | | | | |
| 17 | 1 | 30 | 6 | 2 | 8.00 | 0.20 | 1 | Thermoplastic | P1 | 20 | 0.10 | 2.0 |
| | | | | | | | | (Meth)acrylic | | | | |
| 18 | 1 | 30 | 7 | 15 | 8.00 | 0.20 | 1 | Thermoplastic | P1 | 20 | 0.10 | 2.0 |
| | | | | | | | | (Meth)acrylic | | | | |
| 19 | 1 | 30 | 8 | 1 | 8.00 | 0.20 | 1 | Thermoplastic | P1 | 20 | 0.10 | 2.0 |
| | | | | | | | | (Meth)acrylic | | | | |
| 20 | 1 | 30 | 9 | 20 | 8.00 | 0.20 | 1 | Thermoplastic | P1 | 20 | 0.10 | 2.0 |
| | | | | | | | | (Meth)acrylic | | | | |
| 101 | 1 | 30 | 101 | 25 | 0.05 | 0.30 | 101 | PET | — | — | 0.01 | 30.0 |
| 102 | 1 | 30 | 101 | 25 | 0.05 | 0.30 | 102 | Thermoplastic | — | — | 0.07 | 4.3 |
| | | | | | | | | (Meth)acrylic | | | | |
| 103 | 1 | 30 | 102 | 5 | 8.00 | 0.05 | 1 | Thermoplastic | P1 | 20 | 0.10 | 0.5 |
| | | | | | | | | (Meth)acrylic | | | | |
| 104 | 1 | 30 | 103 | 5 | 0.50 | 0.40 | 1 | Thermoplastic | P1 | 20 | 0.10 | 4.0 |
| | | | | | | | | (Meth)acrylic | | | | |
| 105 | 1 | 30 | 104 | 5 | 0.40 | 0.30 | 1 | Thermoplastic | P1 | 20 | 0.10 | 3.0 |
| | | | | | | | | (Meth)acrylic | | | | |
| 106 | 1 | 30 | 105 | 5 | 11.00 | 0.14 | 1 | Thermoplastic | P1 | 20 | 0.10 | 1.4 |
| | | | | | | | | (Meth)acrylic | | | | |

TABLE 2

| | Evaluation | | | |
|---|---|---|---|---|
| Laminate | Bending | Pen Drop | Falling Ball | |
| No. | Test | Test | Test | Remarks |
| 1 | AAA | AAA | AAA | Example |
| 2 | AA | AAA | AAA | Example |
| 3 | AA | AAA | AA | Example |
| 4 | AA | AA | AAA | Example |
| 6 | AA | AAA | AA | Example |
| 7 | AA | AA | AA | Example |
| 8 | AAA | AAA | AA | Example |
| 9 | AAA | AA | AAA | Example |
| 10 | A | AA | AA | Example |
| 11 | AA | A | AA | Example |
| 12 | AAA | AAA | AAA | Example |
| 13 | AAA | AAA | AA | Example |
| 14 | AA | AAA | AA | Example |
| 15 | AA | A | A | Example |
| 16 | A | AAA | AA | Example |
| 17 | AA | AAA | AA | Example |
| 18 | AAA | AA | AA | Example |
| 19 | A | AAA | AA | Example |
| 20 | AA | AA | AA | Example |
| 101 | AA | B | B | Comparative Example |
| 102 | B | B | B | Comparative Example |
| 103 | A | AA | B | Comparative Example |
| 104 | B | B | AA | Comparative Example |
| 105 | B | B | AA | Comparative Example |

It is understood from Examples and Comparative Examples that the laminate of the present invention can achieve both impact resistance and flexibility in the glass layer.

Comparison of Laminates 1 to 4 shows that when the storage elastic modulus of the elastic layer at 25 °C is in the range of 1.2 to 8. 0 MPa, the impact resistance and the flexibility of the glass layer are improved.

Comparison between Laminates 1 and 6 shows that when the value of the ratio of the loss tangents (tan δ₁/tan δ₂) satisfies the above Formula (2), the impact resistance and the flexibility of the glass layer are improved. In addition, it is found that damage to the internal module can be further suppressed.

Comparison of Laminates 8 to 11 shows that when the content of the rubber particles is in the range of 10 to 80% by mass with respect to the total mass of the optical film, the impact resistance and the flexibility of the glass layer are improved. In addition, it is found that damage to the internal module can be further suppressed.

Comparison of Laminates 1 and 14 to 16 shows that when the thickness of the glass layer is in the range of to 30 μm, the impact resistance and the flexibility of the glass layer are improved.

Comparison of Laminates 17 to 20 shows that when the thickness of the elastic layer is in the range of 2 to 15 μm, the impact resistance and the flexibility of the glass layer are improved.

### INDUSTRIAL APPLICABILITY

The present invention makes it possible to provide a laminate having both impact resistance and flexibility in a glass layer. Furthermore, it is possible to provide a display device having both impact resistance and flexibility using the laminate.

### REFERENCE SIGNS LIST

1 GLASS LAYER
2 ELASTIC LAYER
3 OPTICAL FILM
10 LAMINATE
21 CARRIER SUBSTRATE
22 THIN FILM GLASS
23 CONTACT FILM
24 ELECTROMAGNETIC RADIATION

1. A laminate comprising a glass layer, an elastic layer and an optical film,
wherein a storage elastic modulus of the elastic layer at 25 °C is within a range of 0.5 to 10.0 MPa,
wherein the optical film contains rubber particles, and
wherein, when loss tangents at 25 °C of the elastic layer and the optical film are defined as tan δ₁ and tan δ₂, respectively, a value of a ratio of the loss tangents (tan δ₁/tan δ₂) satisfies Formula (1) below,
1.0≤tan δ₁/tan δ₂≤3.0. Formula (1):

2. The laminate according to claim 1,
wherein the storage elastic modulus of the elastic layer at 25 °C is within a range of 1.2 to 8.0 MPa.

3. The laminate according to claim 1,
wherein the value of the ratio of the loss tangents (tan δ₁/tan δ₂) satisfies Formula (2) below,
1.8≤tan δ₁/tan δ₂≤3.0. Formula (2):

4. The laminate according to claim 1,
wherein a content of the rubber particles is within a range of 10 to 80% by mass relative to a total mass of the optical film.

5. The laminate according to claim 1,
wherein the optical film contains a thermoplastic (meth)acrylic resin.

6. The laminate according to claim 1,
wherein a thickness of the glass layer is within a range of 10 to 30 μm.

7. The laminate according to claim 1,
wherein a thickness of the elastic layer is within a range of 2 to 15 μm.

8. A display device comprising the laminate according to claim 1.

9. The display device according to claim 8,
wherein the glass layer is disposed at a position more outward of the display device than the optical film.
